(19) United States
(12) Patent Application Publication
(10) Pub. No.: US 2011/0076454 A1
(43) Pub. Date: Mar. 31, 2011

(54) RESIN COMPOSITION FOR LASER ENGRAVING, RELIEF PRINTING STARTING PLATE FOR LASER ENGRAVING AND PROCESS FOR PRODUCING SAME, AND RELIEF PRINTING PLATE AND PROCESS FOR MAKING SAME

(75) Inventors: Seiichi HITOMI, Haibara-gun (JP); Atsushi SUGASAKI, Haibara-gun (JP)

(73) Assignee: FUJIFILM CORPORATION, Tokyo (JP)

(21) Appl. No.: 12/887,060

(22) Filed: Sep. 21, 2010

(30) Foreign Application Priority Data
Sep. 25, 2009 (JP) 2009-221126

(51) Int. Cl. G03F 7/20; G03F 7/004

(52) U.S. Cl. 428/156; 430/270.1; 430/306

(57) ABSTRACT

A resin composition for laser engraving is provided that includes (a) a binder polymer having a reactive group, (b) a compound having a hydrophilic group and a bonding group that can react with the reactive group, and (c) a crosslinking agent.

### TECHNICAL FIELD

The present invention relates to a resin composition for laser engraving, a relief printing starting plate for laser engraving and a process for producing same, and a relief printing plate and a process for making same.

### BACKGROUND ART

As a process for forming a printing plate by forming asperities in a photosensitive resin layer layered on a support surface area, a method in which a relief-forming layer formed using a photosensitive composition is exposed to UV light through an original image film to thus selectively cure an image area, and an uncured area is removed using a developer, the so-called ‘analogue plate making’, is well known.

A relief printing plate is a letterpress printing plate having a relief layer with asperities, and such a relief layer with asperities is obtained by patterning a relief-forming layer comprising a photosensitive composition containing as a main component, for example, an elastomeric polymer such as a synthetic rubber, a resin such as a thermoplastic resin, or a mixture of a resin and a plasticizer, thus forming asperities. Among such relief printing plates, one having a soft relief layer is sometimes called a flexographic plate.

When a relief printing plate is made by analogue plate making, since an original image film employing a silver salt material is generally necessary, production time and cost for the original image film are incurred. Furthermore, since development of the original image film requires a chemical treatment, and treatment of development effluent is required, simpler plate making methods, for example, a method that does not use an original image film, a method that does not require development processing, etc. have been examined.

As a plate making process that does not require a development process, the so-called ‘direct engraving CTP method’, in which a relief-forming layer is directly engraved by means of a laser is known. The direct engraving CTP method is a method in which relief-forming asperities are formed by engraving by means of a laser itself, and has the advantage that, unlike relief formation using an original image film, the relief shape can be freely controlled. Because of this, when an image such as an outline character is formed, it is possible to engrave that region more deeply than other regions, or in the case of a fine halftone dot image it is possible, taking into consideration resistance to printing pressure, to engrave while adding a shoulder.

With regard to plate materials that have been used in the direct engraving CTP method so far, a large number of proposals have been made, such as one in which, as a binder that determines the properties of the plate material, a hydrophobic elastomer (rubber) is used (e.g. U.S. Pat. No. 5,798,202) and one in which a hydrophilic polyvinyl alcohol derivative is used (e.g. JP-A-2006-2061 (JP-A denotes a Japanese unexamined patent application publication)).

Furthermore, with regard to a relief printing plate made by the direct engraving CTP method, as methods for easily removing engraving residue formed by laser engraving, those described in JP-A-2004-174758 and JP-A-2008-45102 are known.

JP-A-2004-174758 discloses a laser engraving printing starting plate in which, when a laser-engravable printing starting plate that is formed from a photocured material of a photosensitive resin composition comprising inorganic porous microparticles is subjected to thermogravimetric analysis (TGA) by heating the printing starting plate in a nitrogen atmosphere from room temperature under conditions of a rate of temperature increase of 10° C./min, the temperature at which the percentage weight decrease is 50% is at least 150° C. but no greater than 400° C.

JP-A-2008-45102 discloses a laser-decomposable resin composition comprising (A) a polymer compound having in its main chain at least either a structural unit represented by Formula (1) below or a structural unit represented by Formula (2) below and (B) a binder polymer.

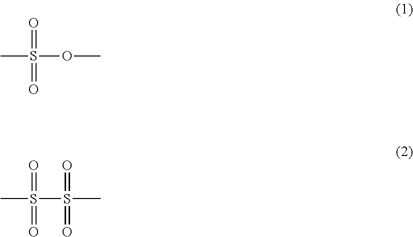

On the other hand, as a lithographic printing starting plate, one from JP-A-2000-39708 is known.

JP-A-2000-39708 discloses a lithographic printing starting plate having, above a support having a hydrophilic surface, a layer comprising (a) a hydrophobic polymer compound having in a side chain a functional group that changes from being hydrophobic to being hydrophilic upon heating and a hydrophilic functional group and (b) a light-absorbing agent that can absorb laser light and convert it to heat.

### SUMMARY OF THE INVENTION

### Problems to be Solved by the Invention

It is an object of the present invention to provide a resin composition for laser engraving that can give a relief printing plate having excellent rinsing properties for engraving residue formed when carrying out laser engraving and having excellent aqueous ink resistance, printing durability, and ink transfer properties, a relief printing starting plate for laser engraving employing the resin composition for laser engraving and a process for producing same, and a relief printing plate and a process for making same.

### Means for Solving the Problems

The above-mentioned object of the present invention has been achieved by means described in <1>, <10>, <11>, <13>, <15>, or <17> below. They are described below together with <2> to <9>, <12>, <14>, and <16>, which are preferred embodiments.
<1> A resin composition for laser engraving comprising (a) a binder polymer having a reactive group, (b) a compound having a hydrophilic group and a bonding group that can react with the reactive group, and (c) a crosslinking agent,
<2> the resin composition for laser engraving according to <1> above, wherein the crosslinking agent (c) comprises the same functional group as the bonding group,
<3> the resin composition for laser engraving according to <1> or <2> above, wherein the bonding group is at least one type of group selected from the group consisting of —SiR¹R²R³, an acid anhydride residue, a methacryloyl group, an acryloyl group, a styryl group, a vinyloxy group, an isocyanate group, a blocked isocyanate group, an amino group, a hydroxy group, —C(═O)—R⁴, an epoxy group, and a mercapto group,
(R¹ to R³ in —SiR¹R²R³ above independently denote a hydrogen atom, a halogen atom, or a monovalent organic group, at least one of R¹ to R³ is an alkyl group, an alkoxy group, or a halogen atom, and R⁴ in —C(═O)—R⁴ above denotes a hydrogen atom or an alkyl group)
<4> the resin composition for laser engraving according to any one of <1> to <3> above, wherein the number of bonding groups in the compound (b) having a hydrophilic group and a bonding group that can react with the reactive group is one,
<5> the resin composition for laser engraving according to any one of <1> to <4> above, wherein the hydrophilic group is at least one type of group selected from the group consisting of a sulfonic acid group, a phosphoric acid group, a phosphoric acid group, a carboxylic acid group, a hydroxy group, an amide group, and an amino group,
<6> the resin composition for laser engraving according to any one of <1> to <5> above, wherein the compound (b) having a hydrophilic group and a bonding group that can react with the reactive group is a compound represented by Formula (1) below,

R^{a}-L-(-R^{b})ₘ (1)

(in Formula (1), R^{a} denotes a bonding group that can react with the reactive group, R^{b} denotes a hydrophilic group, m denotes an integer of 1 to 3, and L denotes a single bond or an (m+1)-valent organic linking group)
<7> the resin composition for laser engraving according to any one of <1> to <6> above, wherein it further comprises (d) a crosslinking promoter,
<8> the resin composition for laser engraving according to any one of <1> to <7> above, wherein it further comprises (e) a photothermal conversion agent,
<9> the resin composition for laser engraving according to any one of <1> to <8> above, wherein it comprises a polymerization initiator and a polymerizable compound,
<10> a relief printing starting plate for laser engraving, comprising a relief-forming layer comprising the resin composition for laser engraving according to any one of <1> to <9> above,
<11> a relief printing starting plate for laser engraving having a crosslinked relief-forming layer formed by crosslinking a relief-forming layer comprising the resin composition for laser engraving according to any one of <1> to <9> above,
<12> the relief printing starting plate for laser engraving according to <11> above, wherein the crosslinked relief-forming layer has a Shore A hardness of at least 50° but no greater than 90°,
<13> a process for producing a relief printing starting plate for laser engraving, comprising a layer formation step of forming a relief-forming layer from the resin composition for laser engraving according to any one of <1> to <9> above and a crosslinking step of crosslinking the relief-forming layer by heat and/or light to thus obtain a relief printing starting plate having a crosslinked relief-forming layer,
<14> the process for producing a relief printing starting plate for laser engraving according to <13> above, wherein the crosslinking step is a step of crosslinking the relief-forming layer by heat,
<15> a process for making a relief printing plate, comprising a layer formation step of forming a relief-forming layer from the resin composition for laser engraving according to any one of <1> to <9> above, a crosslinking step of crosslinking the relief-forming layer by heat and/or light to thus obtain a relief printing starting plate having a crosslinked relief-forming layer, and an engraving step of laser-engraving the relief printing starting plate having a crosslinked relief-forming layer to thus form a relief layer,
<16> the process for making a relief printing plate according to <15> above, wherein the relief layer has a thickness of at least 0.05 mm but no greater than 10 mm, and
<17> a relief printing plate made by the process for making a relief printing plate according to <15> or <16> above.

### BRIEF DESCRIPTION OF DRAWINGS

FIG. 1: A schematic configuration diagram (perspective view) showing plate making equipment comprising fiber-coupled semiconductor laser recording equipment that can be used in the present invention.

### MODE FOR CARRYING OUT THE INVENTION

The present invention is explained in detail below.

### (Resin Composition for Laser Engraving)

The resin composition for laser engraving of the present invention (hereinafter, also simply called the ‘resin composition of the present invention’) comprises (a) a binder polymer having a reactive group (hereinafter, also called a ‘specific polymer’ or ‘component (a)’), (b) a compound having a hydrophilic group and a bonding group that can react with the reactive group (hereinafter, also called a ‘specific hydrophilic compound’ or ‘component (b)’), and (c) a crosslinking agent (hereinafter, also called ‘component (c)’).

It is surmised that, since the resin composition of the present invention comprises the specific hydrophilic compound, the specific polymer and the specific hydrophilic compound react with each other, a hydrophilic group originating from the specific hydrophilic compound is introduced into the specific polymer, and this promotes hydrophilization of engraving residue itself. Subsequently, laser engraving is carried out and engraving residue is formed; it is surmised that the water solubility or water dispersibility of the engraving residue is improved by the action of the hydrophilic group, and the rinsing properties of the engraving residue are improved. It is also surmised that, with regard to aqueous ink resistance, due to a crosslinking agent being contained, a crosslinking reaction with the binder proceeds, thus suppressing penetration of aqueous ink and making it possible to carry out printing without any problems.

The resin composition of the present invention may be used, without particular limitations, in a wide rage of applications in which a resin molded article that is to be laser-engraved is formed. With regard to embodiments of application of the resin composition of the present invention, specific examples include, but are not limited to, an image-forming layer of an image-forming material that is subjected to image formation by laser engraving, a relief-forming layer of a printing starting plate that is subjected to raised relief formation by laser engraving, an intaglio plate, a stencil plate, and a stamp. The resin composition of the present invention may particularly preferably be used in an image-forming layer of an image-forming material that is subjected to image formation by laser engraving and a relief-forming layer of a relief printing starting plate for laser engraving.

Constituent components of the resin composition for laser engraving are explained below.

### (a) Binder Polymer Having Reactive Group

The resin composition for laser engraving of the present invention comprises (a) a binder polymer having a reactive group (specific polymer).

The binder polymer (a) having a reactive group is a polymer component (binder resin) contained in the resin composition for laser engraving; apart from it containing a reactive group, a usual polymer compound is appropriately selected, and one type or two or more types in combination may be used. In particular, when the resin composition for laser engraving is used in a printing starting plate, it may be selected while taking into consideration various aspects of performance such as laser engraving properties, ink acceptance properties, and engraving residue dispersibility.

Furthermore, the specific polymer preferably has a group that can react with a crosslinkable group of a crosslinking agent, which is described later. Furthermore, the group of the specific polymer that can react with the crosslinkable group may be the same group as the reactive group, or it may be a different group.

As the reactive group of the specific polymer, there can preferably be cited at least one type of group selected from the group consisting of —SiR¹R²R³, an acid anhydride residue, an ethylenically unsaturated group, an isocyanate group, a blocked isocyanate group, an amino group, a hydroxy group, —C(═O)—R⁴, an epoxy group, a carboxylic acid group, and a mercapto group, there can more preferably be cited an ethylenically unsaturated group and/or a hydroxy group and/or a carboxylic acid group, and there can particularly preferably be cited a hydroxy group.

R¹ to R³ in —SiR¹R²R³ independently denote a hydrogen atom, a halogen atom, or a monovalent organic group, and at least one of R¹ to R³ is an alkyl group, an alkoxy group, or a halogen atom. Moreover, R⁴ in —C(═O)—R⁴ denotes a hydrogen atom or an alkyl group.

Preferred examples of the ethylenically unsaturated group include a methacryloyl group, an acryloyl group, a styryl group, and a vinyloxy group.

The blocked isocyanate group is a group that is formed by a reaction between an isocyanate group and a blocking agent and that can regenerate an isocyanate group by thermal decomposition.

Examples of the blocking agent include an alcohol compound, a cyclic amide compound, a ketoxime compound, a phenol compound, and a secondary amine compound. Furthermore, as the blocked isocyanate group, Japanese registered patent No. 3095227 may be referred to.

The temperature at which an isocyanate group is regenerated from the blocked isocyanate group is not particularly limited and may be selected according to the structure of the blocked isocyanate group.

Furthermore, when the specific polymer has a blocked isocyanate group, it is preferable for a relief-forming layer formed from the resin composition of the present invention to undergo crosslinking by heat.

The specific polymer may be used by selecting from a polystyrene resin, polyester resin, polyamide resin, polyurea resin, polyamide imide resin, polyurethane resin, polysulfone resin, polyether sulfone resin, polyimide resin, polycarbonate resin, hydroxyethylene unit-containing hydrophilic polymer, acrylic resin, acetal resin, epoxy resin, polycarbonate resin, rubber, thermoplastic elastomer, cellulose, etc. that has a reactive group.

For improvement of engraving sensitivity, the specific polymer preferably has a glass transition temperature (Tg) of at least 20° C., and it is particularly preferable that it has a glass transition temperature (Tg) of at least 20° C. when combined with a photothermal conversion agent, which is described later. A polymer having a glass transition temperature of at least 20° C. is also called a ‘non-elastomer’ below. That is, an ‘elastomer’ is generally academically defined as a polymer having a glass transition temperature of no greater than normal temperature (ref. Kagaku Dai Jiten 2^{nd} edition (Science Dictionary), Foundation for Advancement of International Science, Maruzen, P. 154). Therefore, a non-elastomer means a polymer having a glass transition temperature of greater than normal temperature. The upper limit for the glass transition temperature of the polymer is not limited, but is preferably no greater than 200° C. from the viewpoint of ease of handling, and is more preferably at least 25° C. but no greater than 120° C.

The content of the reactive group contained in the specific polymer is preferably 0.1 to 15 mmol/g, and more preferably 0.5 to 7 mmol/g.

The weight-average molecular weight (on a polystyrene basis by GPC measurement) of the specific polymer is preferably 5,000 to 500,000, more preferably 10,000 to 400,000, and yet more preferably 15,000 to 300,000. When the weight-average molecular weight is at least 5,000, the shape retention as a single resin is excellent, and when it is no greater than 500,000, it is easily dissolved in a solvent such as water and it is convenient for preparation of the resin composition for laser engraving.

The total content of the specific polymer in the resin composition for laser engraving of the present invention is preferably 5 to 80 wt % relative to the total weight of the solids content of the resin composition for laser engraving, more preferably 15 to 75 wt %, and yet more preferably 20 to 65 wt %. When the content of the specific polymer is at least 5 wt % printing durability that gives a relief printing plate usable as a printing plate is obtained, and when it is no greater than 80 wt % other components do not become insufficient and flexibility that can give a relief printing plate that is usable as a printing plate when used as a flexographic printing plate can be obtained.

### <Polymer Having Hydroxy Group>

The resin composition for laser engraving of the present invention preferably comprises a polymer having a hydroxy group as the specific polymer.

The skeleton of the polymer having a hydroxy group is not particularly limited, and is preferably an acrylic resin, an epoxy resin, a hydroxyethylene unit-containing hydrophilic polymer, a polyvinyl acetal, a polyester resin, a polyurethane resin, or cellulose.

As an acrylic monomer used in synthesis of the acrylic resin having a hydroxy group, for example, a (meth)acrylic acid ester, a crotonic acid ester, or a (meth)acrylamide that has a hydroxy group in the molecule is preferable. Specific examples of such a monomer include 2-hydroxyethyl(meth)acrylate, 2-hydroxypropyl(meth)acrylate, and 4-hydroxybutyl(meth)acrylate. A copolymer formed by polymerization of the above with a known (meth)acrylic-based monomer or vinyl-based monomer is preferably used.

As the polymer having a hydroxy group, it is also possible to use an epoxy resin having a hydroxy group in a side chain. Preferred specific examples thereof include an epoxy resin formed by polymerization, as a starting material monomer, of an adduct of bisphenol A and epichlorohydrin.

As the polyester resin having a hydroxy group, a hydroxycarboxylic acid unit-containing polyester resin such as polylactic acid may preferably be used. As such a polyester resin, specifically, one selected from the group consisting of a polyhydroxyalkanoate (PHA), a lactic acid-based polymer, polyglycolic acid (PGA), polycaprolactone (PCL), polybutylene succinate), derivatives thereof, and mixtures thereof is preferable.

Furthermore, as the polymer having a hydroxy group, a hydroxyethylene unit-containing hydrophilic polymer may be preferably used. As the hydroxyethylene unit-containing hydrophilic polymer, polyvinyl alcohol (PVA) and derivatives thereof are preferably used.

Examples of the PVA derivatives include an acid-modified PVA in which at least some of the hydroxy groups of the hydroxyethylene units are modified with an acid group such as a carboxy group (also called a ‘carboxylic acid group’), a modified PVA in which some of the hydroxy groups are modified with a (meth)acryloyl group, a modified PVA in which at least some of the hydroxy groups are modified with an amino group, a modified PVA in which at least some of the hydroxy groups have introduced thereinto ethylene glycol, propylene glycol, or a multimer thereof, and a polyvinyl acetal obtained by treating polyvinyl alcohol with an aldehyde. Among them, a polyvinyl acetal is particularly preferably used. As the aldehyde used for acetal treatment, acetaldehyde and butylaldehyde are preferably used because of ease of handling. Polyvinyl butyral (PVB) is a particularly preferably used PVA derivative.

Moreover, as the polymer having a hydroxy group, cellulose and a cellulose derivative may preferably be used, and a cellulose derivative may more preferably be used.

Standard cellulose is very difficult to dissolve in water, alcohols, and the like, but by modifying remaining OH in glucopyranose units with a specific functional group it is possible to control the solubility in water or a solvent, and it is also desirable to use, as the specific polymer that can be used in the present invention, a cellulose derivative that is insoluble in water but as described above is made soluble in an alcohol having 1 to 4 carbon atoms.

Examples of the cellulose derivative include an alkylcellulose such as ethylcellulose or methylcellulose, hydroxyethylene cellulose, hydroxypropylene cellulose, and cellulose acetate butyrate. Furthermore, as a specific example thereof, the Metolose series manufactured by Shin-Etsu Chemical Co., Ltd. can be cited. The contents of this series are those in which some of the hydrogen atoms of the hydroxy groups of cellulose are replaced by methyl groups (—CH₃), hydroxypropyl groups (—CH₂CHOHCH₃), or hydroxyethyl groups (—CH₂CH₂OH).

Among them, an alkylcellulose is preferable, and ethylcellulose and/or methylcellulose are more preferable.

### <Polymer Having Ethylenically Unsaturated Group>

The resin composition for laser engraving of the present invention preferably comprises a polymer having an ethylenically unsaturated group as the specific polymer.

A polymer having an ethylenically unsaturated group in a side chain may be obtained by introducing an ethylenically unsaturated group such as an allyl group, an acryloyl group, a methacryloyl group, a styryl group, or a vinyl ether group into a side chain of the skeleton of a binder polymer.

The skeleton of the polymer having an ethylenically unsaturated group is not particularly limited, but preferred examples thereof include a polystyrene resin, a polyester resin, a polyamide resin, a polyurea resin, a polyamide imide resin, a polyurethane resin, a polysulfone resin, a polyether sulfone resin, a polyimide resin, a polycarbonate resin, a hydroxyethylene unit-containing hydrophilic polymer, an acrylic resin, an acetal resin, an epoxy resin, a polycarbonate resin, a rubber, and a thermoplastic elastomer.

As a method for introducing an ethylenically unsaturated group into a binder polymer side chain, a known method such as (1) a method in which a polymer is subjected to copolymerization with a structural unit having an ethylenically unsaturated group precursor structure, and the ethylenically unsaturated group precursor structure is then converted into the ethylenically unsaturated group or (2) a method in which a polymer compound having a plurality of groups such as hydroxy groups, amino groups, epoxy groups, or carboxy groups is prepared, and a compound having an ethylenically unsaturated group and a group that reacts with the above groups is subjected to a polymer reaction may be used. In accordance with these methods, the number of ethylenically unsaturated groups introduced into a polymer compound can be controlled.

Among the above, as the polymer having an ethylenically unsaturated group, a polymer having an acryloyl group, a methacryloyl group, a styryl group, and/or a vinyl ether group is preferable.

### <Polymer Having Carboxy Group>

The resin composition for laser engraving of the present invention may comprise a polymer having a carboxy group as the specific polymer.

The polymer having a carboxy group is not particularly limited, but preferred examples include an acrylic resin having a carboxy group, a polyurethane resin having a carboxy group, and a polyester resin having a carboxy group.

Examples of the acrylic resin having a carboxy group include an acrylic resin formed by copolymerization of acrylic acid or methacrylic acid and one in which an acrylic resin (meth)acrylate-derived ester compound is hydrolyzed to form a carboxy group.

Examples of the polyurethane resin having a carboxy group include a polyurethane resin obtained by polymerization of a polyhydric alcohol having one or more carboxy groups and a polyvalent isocyanate.

Examples of the polyester resin having a carboxy group include a polyester resin formed by polycondensation of a tri- or higher-valent polyvalent carboxylic acid and a diol and a polyester resin formed by using a polyvalent carboxylic acid with a larger number of carboxy groups than the number of hydroxy groups of a polyhydric alcohol.

### <Polymer Having Isocyanate Group>

The resin composition for laser engraving of the present invention may comprise a polymer having an isocyanate group as the specific polymer.

The polymer having an isocyanate group is not particularly limited, but preferred examples thereof include a polyurethane resin having an isocyanate group and a polyester resin having an isocyanate group.

Examples of the polyurethane resin having an isocyanate group include a polyurethane resin formed using a polyvalent isocyanate compound with a larger number of isocyanate groups than the number of hydroxy groups of a polyhydric alcohol.

Examples of the polyester resin having an isocyanate group include a polyester resin formed by a reaction of a polyester resin having two or more hydroxy groups such as polyester diol and a polyvalent isocyanate compound. As the polyester resin having two or more hydroxy groups, those described for the polymer having a hydroxy group are suitably used.

Specific examples of the polymer having an isocyanate group include Coronate L, Coronate HL, Coronate 2030, Aquanate 100, Aquanate 105, and Aquanate 120, which are manufactured by Nippon Polyurethane Industry Co., Ltd.

### <Polymer Having Epoxy Group>

The resin composition for laser engraving of the present invention may comprise a polymer having an epoxy group as the specific polymer.

The polymer having an epoxy group is not particularly limited, but preferred examples thereof include a novolac type epoxy resin, a bisphenol-based epoxy resin, an alicyclic epoxy resin, a hydantoin type epoxy resin, a polyurethane resin having an epoxy group, and a polyester resin having an epoxy group, more preferred examples thereof include a bisphenol-based epoxy resin, and yet more preferred examples thereof include a bisphenol A-based epoxy resin.

### <Polymer Having Acid Anhydride Residue>

The resin composition for laser engraving of the present invention may comprise a polymer having an acid anhydride residue as the specific polymer.

The polymer having an acid anhydride residue is not particularly limited, but is preferably a polymer having a carboxylic acid anhydride residue, and more preferably a polymer having a carboxylic acid anhydride residue with a 5- or 6-membered ring structure.

Examples of the polymer having an acid anhydride residue include a polymer having an acid anhydride residue obtained by a reaction of the polymer having an isocyanate group and a compound having a hydroxy group and an acid anhydride residue and a polymer having an acid anhydride residue obtained by dehydrating some of the carboxy groups of an acrylic resin formed by copolymerization of acrylic acid or methacrylic acid.

### <Polymer Having Amino Group>

The resin composition for laser engraving of the present invention may comprise a polymer having an amino group as the specific polymer.

The polymer having an amino group is not particularly limited, but preferred examples thereof include a polyalkylene imine, polyallylamine, and an acrylic resin having an aminoalkyl group in a side chain.

As a monomer used for synthesis of the acrylic resin having an aminoalkyl group in a side chain, N,N-dimethylaminoethyl(meth)acrylate, N,N-diethylaminoethyl(meth)acrylate, and N,N-dimethylaminopropyl(meth)acrylate are preferably cited.

### <Polymer Having —SiR¹R²R³>

When the crosslinkable group of the crosslinking agent is a group that can react with —SiR¹R²R³, the resin composition of the present invention preferably comprises a polymer having —SiR¹R²R³.

R¹ to R³ independently denote a hydrogen atom, a halogen atom, or a monovalent organic group. At least one of R¹ to R³ is an alkyl group, an alkoxy group, a hydroxy group, or a halogen atom.

The polymer having —SiR¹R²R³ is not particularly limited, but preferred examples thereof include a polymer having a silanol group and a polymer having a trialkoxysilyl group.

From the viewpoint of rinsing properties and printing durability, the alkoxy group denoted by R¹ to R³ is preferably an alkoxy group having 1 to 30 carbon atoms, more preferably an alkoxy group having 1 to 15 carbon atoms, and yet more preferably an alkoxy group having 1 to 5 carbon atoms.

Examples of the halogen atom denoted by R¹ to R³ include an F atom, a Cl atom, a Br atom, and an I atom, and from the viewpoint of ease of synthesis and stability it is preferably a Cl atom or a Br atom, and more preferably a Cl atom.

With regard to —SiR¹R²R³ above, it is preferable that at least one of R¹ to R³ is a hydroxy group, a methoxy group, or an ethoxy group.

(b) Compound Having Hydrophilic Group and Bonding Group that can React with the Above Reactive Group

The resin composition of the present invention comprises (b) a compound (specific hydrophilic compound) having a hydrophilic group and a bonding group that can react with the reactive group.

The bonding group of the specific hydrophilic compound is not particularly limited as long as it is a group that can react with a reactive group of the specific polymer used, but at least one type of group selected from the group consisting of —SiR¹R²R³, an acid anhydride residue, an ethylenically unsaturated group, an isocyanate group, a blocked isocyanate group, an amino group, a hydroxy group, —C(═O)—R⁴, an epoxy group, and a mercapto group can be cited as a preferred example, at least one type of group selected from the group consisting of —SiR¹R²R³, an ethylenically unsaturated group, an isocyanate group, a blocked isocyanate group, and an epoxy group can be cited as a more preferred example, at least one type of group selected from the group consisting of —SiR¹R²R³, an isocyanate group, a blocked isocyanate group, and an epoxy group can be cited as a yet more preferred example, and —SiR¹R²R³ can be cited as a particularly preferred example.

R¹ to R³ in —SiR¹R²R³ independently denote a hydrogen atom, a halogen atom, or a monovalent organic group, at least one of R¹ to R³ is an alkyl group, an alkoxy group, or a halogen atom, it is preferable that at least one of R¹ to R³ is an alkoxy group or a halogen atom, it is more preferable that at least two of R¹ to R³ are alkoxy groups or halogen atoms, it is yet more preferable that all of R¹ to R³ are alkoxy groups or halogen atoms, and it is most preferable that all of R¹ to R³ are alkoxy groups.

Furthermore, R⁴ in —C(═O)—R⁴ above denotes a hydrogen atom or an alkyl group.

Preferred examples of the ethylenically unsaturated group include a methacryloyl group, an acryloyl group, a styryl group, and a vinyloxy group.

Furthermore, the blocked isocyanate group is a group that is formed by reaction of an isocyanate group and a blocking agent and can thermally decompose to regenerate an isocyanate group, and examples thereof include those described above.

The number of reactive groups in the specific hydrophilic compound is particularly preferably 1.

Examples of the hydrophilic group of the specific hydrophilic compound include an acid group, a hydroxy group, an amide group, and an amino group; an acid group, an amide group, and an amino group are preferable, and an acid group is more preferable.

Preferred examples of the acid group include a carboxylic acid group, a sulfonic acid group, a phosphoric acid group, and a phosphonic acid group, and from the viewpoint of solubility in an organic solvent a carboxylic acid group is particularly preferable.

Moreover, preferred examples of the amide group include a carboxylic acid amide group and a sulfonic acid amide group; a sulfonic acid amide group is more preferable.

Furthermore, these hydrophilic groups may form a salt, and examples thereof include —COOM, —SO₃M, —OPO₃M₂, —OPO₂(OH)M, —PO₃M₂, —PO₂(OH)M, —OM, and an ammonium salt residue. M may be a monovalent cation or a polyvalent cation.

The number of hydrophilic groups of the specific hydrophilic compound is preferably 1 to 6, more preferably 1 to 3, yet more preferably 1 or 2, and particularly preferably 1.

The bonding group and the hydrophilic group of the specific hydrophilic compound may be directly bonded to each other or may be bonded via a polyvalent organic linking group.

The polyvalent organic linking group is preferably a group having at least one bond selected from the group consisting of an ester bond, a thioester bond, an amide bond, an ether bond, a thioether bond, a urethane bond, a thiourethane bond, a urea bond, a thiourea bond, and an amino bond (—N(R^{A})—; R^{A} denotes a monovalent organic group), and is more preferably a group in which at least one bond selected from the group consisting of an ester bond, a thioester bond, an amide bond, an ether bond, a thioether bond, a urethane bond, a thiourethane bond, a urea bond, a thiourea bond, and an amino bond (—N(R^{A})—; R^{A} denotes a monovalent organic group) and two or more polyvalent hydrocarbon groups are combined.

The polyvalent organic linking group is preferably a group having at least one thioether bond.

The polyvalent hydrocarbon group may be a polyvalent aliphatic hydrocarbon group, a polyvalent aromatic hydrocarbon group, or a combination thereof. The polyvalent aliphatic hydrocarbon group may be straight chain, branched, or cyclic. The polyvalent hydrocarbon group may have a monovalent hydrocarbon group as a substituent.

From the viewpoint of hydrophilicity, the pKa of the specific hydrophilic compound is preferably −5 to 11, more preferably 0 to 7, and yet more preferably 2 to 5.

The specific hydrophilic compound that can be used in the present invention is preferably a compound represented by Formula (1) below.

R^{a}-L-(-R^{b})ₘ (1)

R^{a} in Formula (1) denotes a bonding group that can react with the reactive group, and R^{b} denotes a hydrophilic group. The bonding group denoted by R^{a} and the hydrophilic group denoted by R^{b} have the same meanings as those of the bonding group and hydrophilic group of the specific hydrophilic compound, and preferred ranges are also the same.

The number m of R^{b}s in Formula (1) denotes an integer of 1 to 3, and is preferably 1 or 2, and more preferably 1.

L in Formula (1) denotes a single bond or an (m+1)-valent organic linking group.

The (m+1)-valent organic linking group is preferably an (m+1)-valent group having at least one bond selected from the group consisting of an ester bond, a thioester bond, an amide bond, an ether bond, a thioether bond, a urethane bond, a thiourethane bond, a urea bond, a thiourea bond, and an amino bond (—N(R^{A})—; R^{A} denotes a monovalent organic group), and is more preferably an (m+1)-valent group formed by combining two or more polyvalent hydrocarbon groups and at least one bond selected from the group consisting of an ester bond, a thioester bond, an amide bond, an ether bond, a thioether bond, a urethane bond, a thiourethane bond, a urea bond, a thiourea bond, and an amino bond (—N(R^{A})—; R^{A} denotes a monovalent organic group).

Furthermore, the (m+1)-valent organic linking group is preferably a group having at least one thioether bond.

Specific preferred examples of the specific hydrophilic compound that can be used in the present invention include A-1 to A-16 below, but needless to say the specific hydrophilic compound that can be used in the present invention is not limited thereto.

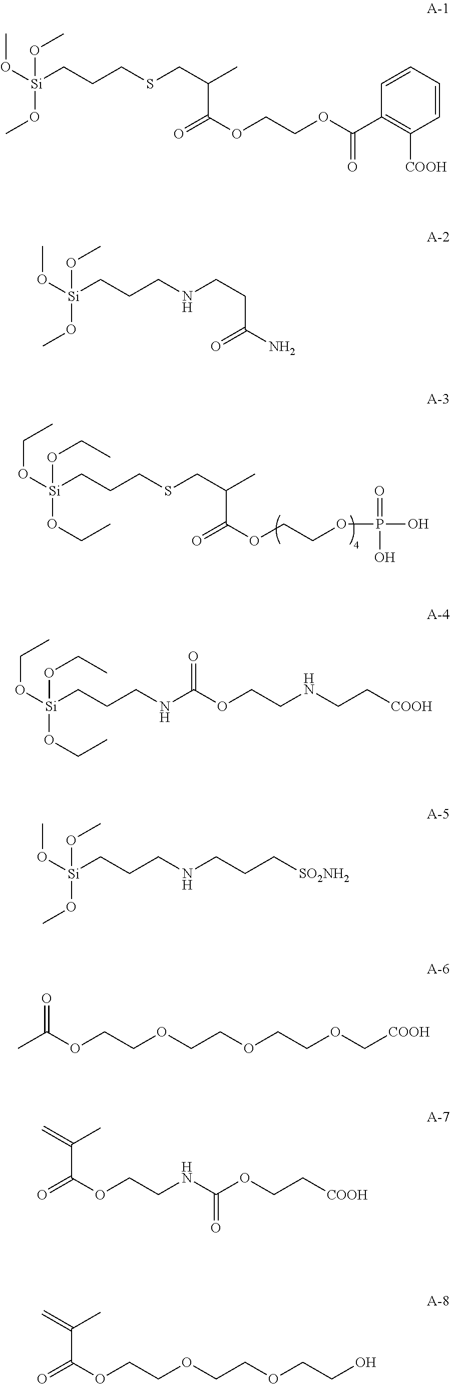

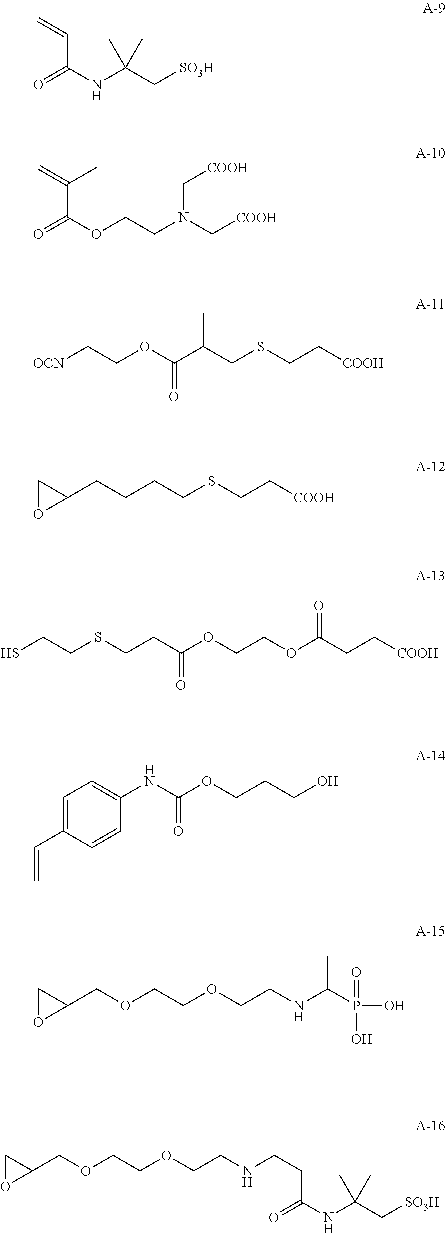

Among them, A-1, A-3, A-9, A-11, A-12, A-15, and A-16 are preferable, and A-1 is particularly preferable.

From the viewpoint of achieving a balance between film strength and film flexibility, the amount of specific hydrophilic compound added in the resin composition of the present invention when the total solids content excluding solvent is 100 wt % is preferably 0.1 to 70 wt %, more preferably 1 to 40 wt %, and particularly preferably 5 to 20 wt %.

Furthermore, the ratio (ratio by weight) of the specific hydrophilic compound to the specific polymer used in the resin composition of the present invention is preferably specific hydrophilic compound:specific polymer=10:90 to 90:10, more preferably 20:80 to 70:30, and yet more preferably 20:80 to 50:50.

Moreover, the ratio (ratio by weight) of the specific hydrophilic compound to a crosslinking agent, which is described later, used in the resin composition of the present invention is preferably specific hydrophilic compound:crosslinking agent=10:90 to 90:10, more preferably 20:80 to 70:30, and yet more preferably 40:60 to 70:30.

### <Combination of the Reactive Group and the Bonding Group>

In the resin composition for laser engraving of the present invention, the combination of the reactive group of the binder polymer (a) having a reactive group and the bonding group of the compound (b) having a hydrophilic group and a bonding group that can react with the reactive group is not particularly limited as long as it is a combination of a reactive group and a bonding group that can react with the reactive group; a combination selected from the group consisting of (ab-1) to (ab-22) below is preferable, a combination selected from the group consisting of (ab-1) to (ab-13) and (ab-17) below is more preferable, a combination selected from the group consisting of (ab-1) to (ab-4) and (ab-17) below is yet more preferable, and the combination of (ab-1) below is particularly preferable.

TABLE 1

| | Reactive group | Bonding group |
|---|---|---|
| (ab-1) | Hydroxy group | —SiR¹R²R³ |
| (ab-2) | Hydroxy group | Acid anhydride residue |
| (ab-3) | Hydroxy group | Isocyanate group |
| (ab-4) | Hydroxy group | Epoxy group |
| (ab-5) | Isocyanate group | Hydroxy group |
| (ab-6) | Isocyanate group | Carboxy group |
| (ab-7) | Isocyanate group | Amino group |
| (ab-8) | Isocyanate group | Isocyanate group |
| (ab-9) | Isocyanate group | Epoxy group |
| (ab-10) | Epoxy group | Hydroxy group |
| (ab-11) | Epoxy group | Amino group |
| (ab-12) | Epoxy group | Carboxy group |
| (ab-13) | Epoxy group | Isocyanate group |
| (ab-14) | Amino group | Isocyanate group |
| (ab-15) | Amino group | Epoxy group |
| (ab-16) | Amino group | Acid anhydride residue |
| (ab-17) | Carboxy group | —SiR¹R²R³ |
| (ab-18) | Carboxy group | Isocyanate group |
| (ab-19) | Carboxy group | Epoxy group |
| (ab-20) | —SiR¹R²R³ | Hydroxy group |
| (ab-21) | Acid anhydride residue | Hydroxy group |
| (ab-22) | Acid anhydride residue | Amino group |

### (c) Crosslinking Agent

The resin composition for laser engraving of the present invention preferably comprises a crosslinking agent.

In the present invention, from the viewpoint of forming a crosslinked structure in a relief-forming layer, the resin composition for laser engraving preferably comprises a crosslinking agent in order to form the crosslinked structure.

The crosslinking agent that can be used in the present invention is not particularly limited as long as polymerization as a result of a chemical reaction due to light or heat (a radical polymerization reaction or a crosslinking reaction employing an acid/base as an initiating species, etc.) to thus cure a relief-forming layer is possible. In particular, it is preferable to use (1) a compound having an ethylenically unsaturated group (hereinafter, also called a ‘polymerizable compound’), (2) a crosslinking agent having —SiR¹R²R³ (R¹ to R³ independently denote a hydrogen atom, a halogen atom, or a monovalent organic group, and at least one of R¹ to R³ is an alkyl group, an aryl group, an alkoxy group, a hydroxy group, or a halogen atom), and (3) a compound having a plurality of at least one group selected from the group consisting of an acid anhydride residue, an isocyanate group, a hydroxy group, an amino group, a blocked isocyanate group, a carboxy group, and an epoxy group.

These compounds may form a crosslinked structure in the relief-forming layer by a reaction with the above-mentioned binder, may form a crosslinked structure by a reaction of these compounds themselves, or may form a crosslinked structure by both of these reactions.

Furthermore, the crosslinking agent that can be used in the present invention preferably has the same functional group as the bonding group of the compound (b) having a hydrophilic group and a bonding group that can react with the reactive group, and more preferably has the same group as the bonding group. ‘The same functional group’ is a group that exhibits similar reactivity and, for example, groups described as an ethylenically unsaturated group, —SiR¹R²R³, an acid anhydride residue, a blocked isocyanate group, etc. are respectively referred to as ‘the functional group’. Specifically, for example, groups represented by —SiR¹R²R³ (R¹ to R³ independently denote a hydrogen atom, a halogen atom, or a monovalent organic group, and at least one of R¹ to R³ is an alkyl group, an aryl group, an alkoxy group, a hydroxy group, or a halogen atom) are all considered to be the same functional group.

The molecular weight of these crosslinking agents is not particularly limited, but is preferably 50 to 3,000, more preferably 70 to 2,500, and yet more preferably 100 to 2,000.

From the viewpoint of flexibility and brittleness of a crosslinked film, the total content of the crosslinking agent in the resin composition for laser engraving of the present invention is preferably in the range of 10 to 60 wt % relative to nonvolatile components, and more preferably in the range of 15 to 45 wt %.

### <(1) Polymerizable Compound>

The ‘polymerizable compound’ referred to in the present invention means a compound having at least one ethylenically unsaturated group.

The ethylenically unsaturated group is not particularly limited; a (meth)acryloyl group, a vinyl group, an allyl group, etc. are preferably used, and a (meth)acryloyl group is particularly preferably used.

Examples of monofunctional polymerizable compounds include unsaturated carboxylic acids such as acrylic acid, methacrylic acid, itaconic acid, crotonic acid, isocrotonic acid, and maleic acid and salts thereof, an ethylenically unsaturated group-containing anhydride, a (meth)acrylate, a (meth)acrylamide, an acrylonitrile, a styrene, and various types of polymerizable compounds such as an unsaturated polyester resin, an unsaturated polyether resin, an unsaturated polyimide resin, and an unsaturated urethane resin.

Furthermore, preferred examples of the monofunctional polymerizable compound used include acrylic acid derivatives such as methyl acrylate, ethyl acrylate, n-butyl acrylate, 2-ethylhexyl acrylate, 2-hydroxyethyl acrylate, butoxyethyl acrylate, carbitol acrylate, cyclohexyl acrylate, benzyl acrylate, N-methylolacrylamide, and epoxy acrylate, methacrylic acid derivatives such as methyl methacrylate, N-vinyl compounds such as N-vinylpyrrolidone and N-vinylcaprolactam, and allyl compounds such as allyl glycidyl ether, diallyl phthalate, and triallyl trimellitate.

Examples of polyfunctional polymerizable compounds include ester or amide compounds of an unsaturated carboxylic acid and a polyhydric alcohol compound or a polyvalent amine compound, such as ethylene glycol diacrylate, triethylene glycol diacrylate, propylene glycol diacrylate, triethylene glycol dimethacrylate, 1,3-butanediol diitaconate, pentaerythritol dicrotonate, sorbitol tetramalate, methylenebismethacrylamide, and 1,6-hexamethylenebisacrylamide, urethane acrylates described in JP-A-51-37193, polyester acrylates described in JP-A-48-64183, JP-B-49-43191 (JP-B denotes a Japanese examined patent application publication) and JP-B-52-30490, and a polyfunctional acrylate or methacrylate such as an epoxy acrylate formed by reaction of an epoxy resin and (meth)acrylic acid. Furthermore, radically polymerizable or crosslinkable monomers and oligomers that are commercial products or are industrially known, such as those described in Journal of the Adhesion Society of Japan, Vol. 20, No. 7, pp. 300 to 308 (1984); ‘Kakyozai Handobukku’ (Crosslinking Agent Handbook), Ed. S. Yamashita (Taiseisha, 1981); ‘UV•EB Koka Handobukku (Genryohen)’ (UV•EB Curing Handbook (Starting Materials)) Ed. K. Kato (Kobunshi Kankoukai, 1985); ‘UV•EB Koka Gijutsu no Oyo to Shijyo’ (Application and Market of UV•EB Curing Technology), p. 79, Ed. RadTech (CMC, 1989); and E. Takiyama ‘Poriesuteru Jushi Handobukku’ (Polyester Resin Handbook), (The Nikkan Kogyo Shimbun Ltd., 1988) may be used.

In the relief printing starting plate of the present invention, which is described later, since a preferred mode is one in which there is a crosslinked relief-forming layer having a crosslinked structure in the film, a polyfunctional polymerizable compound is preferably used.

The molecular weight of these polymerizable compounds is not particularly limited, but is preferably 50 to 3,000, more preferably 70 to 2,500, and particularly preferably 100 to 2,000.

From the viewpoint of flexibility and brittleness of the crosslinked film, the total content of the polymerizable compound in the resin composition for laser engraving of the present invention is preferably in the range of 10 to 60 wt % relative to nonvolatile components, and more preferably in the range of 15 to 45 wt %.

When a polymerizable compound is used as the crosslinking agent, it is preferable to use a polymer having an ethylenically unsaturated group in the molecule as the binder polymer (a) having a reactive group, but another binder polymer may be used.

### <(2) Crosslinking Agent Having —SiR¹R²R³>

As the crosslinking agent that can be used in the present invention, a crosslinking agent having at least —SiR¹R²R³ as a crosslinkable group can preferably be cited, and a crosslinking agent having two or more —SiR¹R²R³ can more preferably be cited.

R¹ to R³ independently denote a hydrogen atom, a halogen atom, or a monovalent organic group. At least one of R¹ to R³ is an alkyl group, an alkoxy group, a hydroxy group, or a halogen atom.

It is preferable that at least two of R¹ to R³ are alkoxy groups or halogen atoms, and it is particularly preferable that R¹ to R³ are independently alkoxy groups or halogen atoms. From the viewpoint of ease of handling a compound it is preferable that at least two of R¹ to R³ are alkoxy groups.

From the viewpoint of rinsing properties and printing durability, the alkoxy group denoted by R¹ to R³ above is preferably an alkoxy group having 1 to 30 carbon atoms, more preferably an alkoxy group having 1 to 15 carbon atoms, and yet more preferably an alkoxy group having 1 to 5 carbon atoms.

Furthermore, examples of the halogen atom denoted by R¹ to R³ above include an F atom, a Cl atom, a Br atom, and an I atom; from the viewpoint of ease of synthesis and stability a Cl atom and a Br atom are preferable, and a Cl atom is more preferable.

Among the above, it is preferable that all of R¹ to R³ are methoxy groups or ethoxy groups.

A crosslinking agent having two or more —SiR¹R²R³ is also preferably used. A crosslinking agent having two to six —SiR¹R²R³ is preferably used. As a group that links two or more —SiR¹R²R³ in a crosslinking agent having two or more —SiR¹R²R³, a di- or higher-valent organic group can be cited; from the viewpoint of high engraving sensitivity a heteroatom (N, S, O)-containing di- or higher-valent organic group is preferable, and an S atom-containing di- or higher-valent organic group is more preferable.

As a crosslinking agent having at least —SiR¹R²R³, a compound having in the molecule two groups in which a methoxy group or ethoxy group is bonded to an Si atom and the Si atoms are bonded via an alkylene group containing a heteroatom, and particularly preferably an S atom, is suitable.

Examples of the crosslinking agent having —SiR¹R²R³ include vinyltrichlorosilane, vinyltrimethoxysilane, vinyltriethoxysilane, β-(3,4-epoxycyclohexyl)ethyltrimethoxysilane, γ-glycidoxypropyltrimethoxysilane, γ-glycidoxypropylmethyldiethoxysilane, γ-glycidoxypropyltriethoxysilane, γ-methacryloxypropylmethyldimethoxysilane, γ-methacryloxypropyltrimethoxysilane, γ-methacryloxypropylmethyldiethoxysilane, γ-methacryloxypropyltriethoxysilane, γ-acryloxypropyltrimethoxysilane, N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltrimethoxysilane, γ-aminopropyltriethoxysilane, N-phenyl-γ-aminopropyltrimethoxysilane, γ-mercaptopropyltrimethoxysilane, γ-chloropropyltrimethoxysilane, and γ-ureidopropyltriethoxysilane.

Specific preferred examples of the crosslinking agent having —SiR¹R²R³ that can be used in the present invention include compounds represented by the formulae below, but the present invention should not be construed as being limited to these compounds. Et and Me in the formulae below denote an ethyl group and a methyl group respectively.

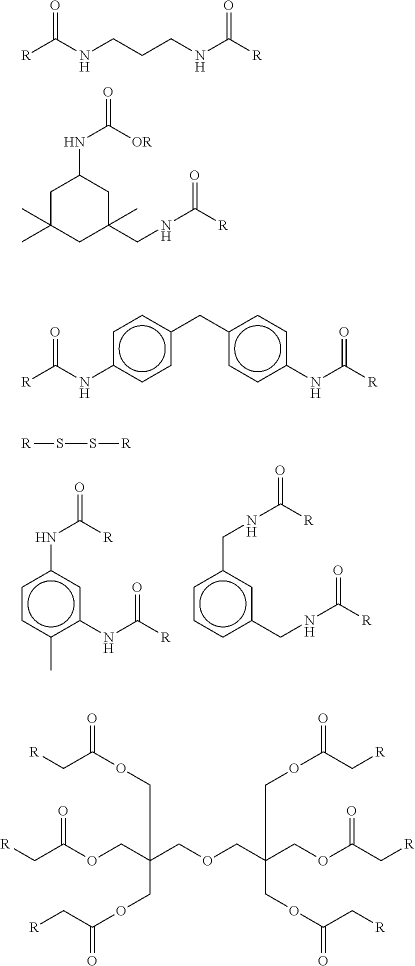

In each of the formulae above, R denotes a partial structure selected from the structures below. When a plurality of Rs and R¹s are present in the molecule, they may be identical to or different from each other, and are preferably identical to each other in terms of synthetic suitability.

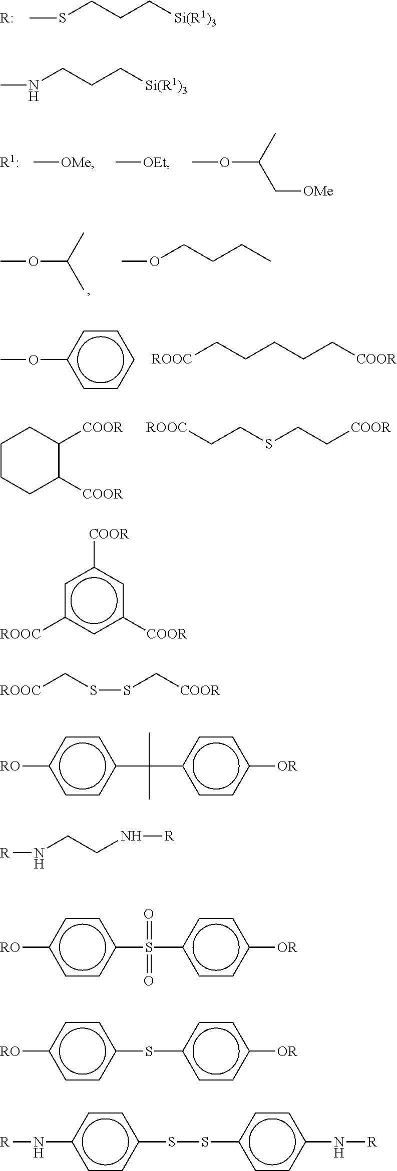

In each of the formulae above, R denotes a partial structure shown below. R¹ is the same as defined above. When a plurality of Rs and R¹s are present in the molecule, they may be identical to or different from each other, and in terms of synthetic suitability are preferably identical to each other.

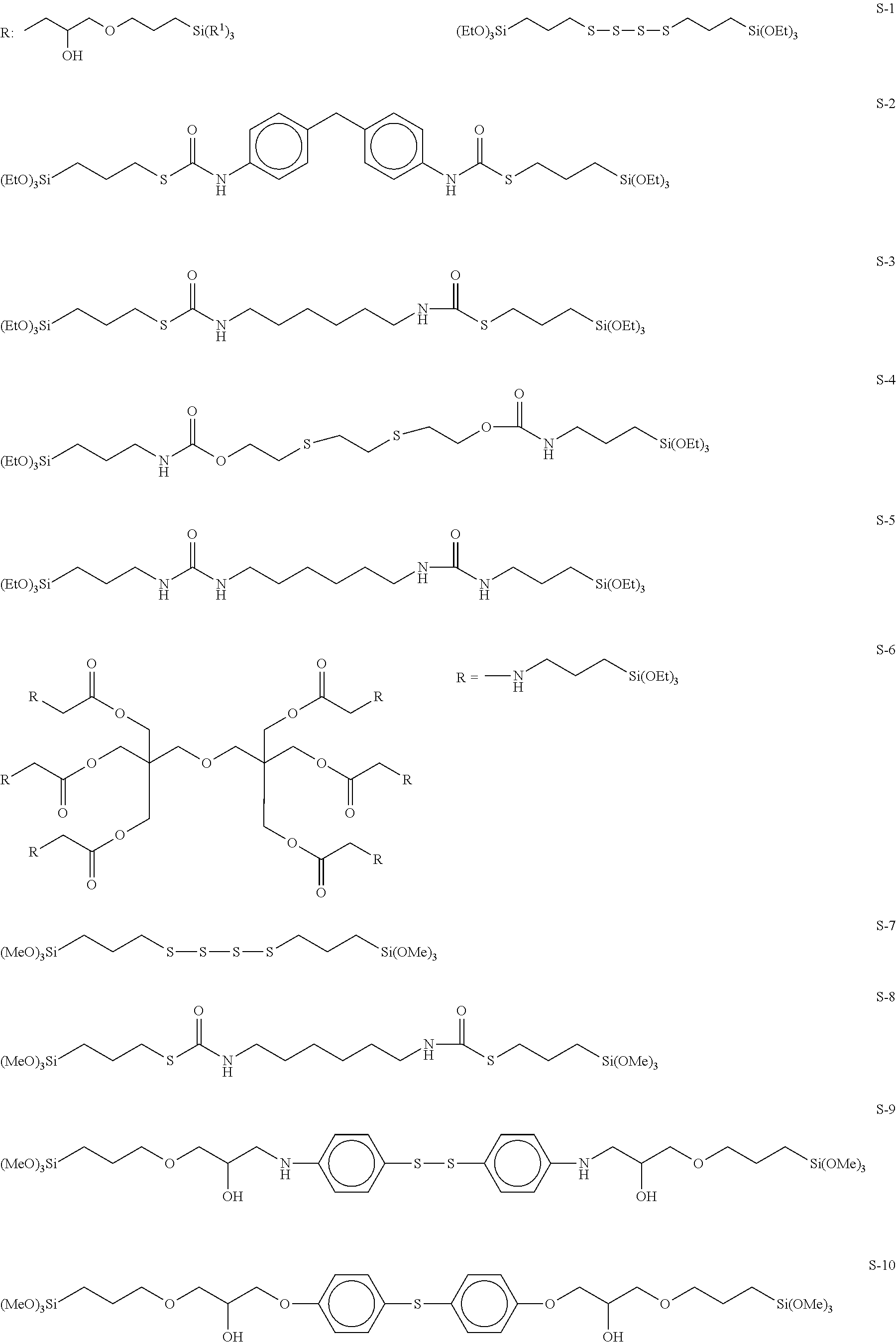

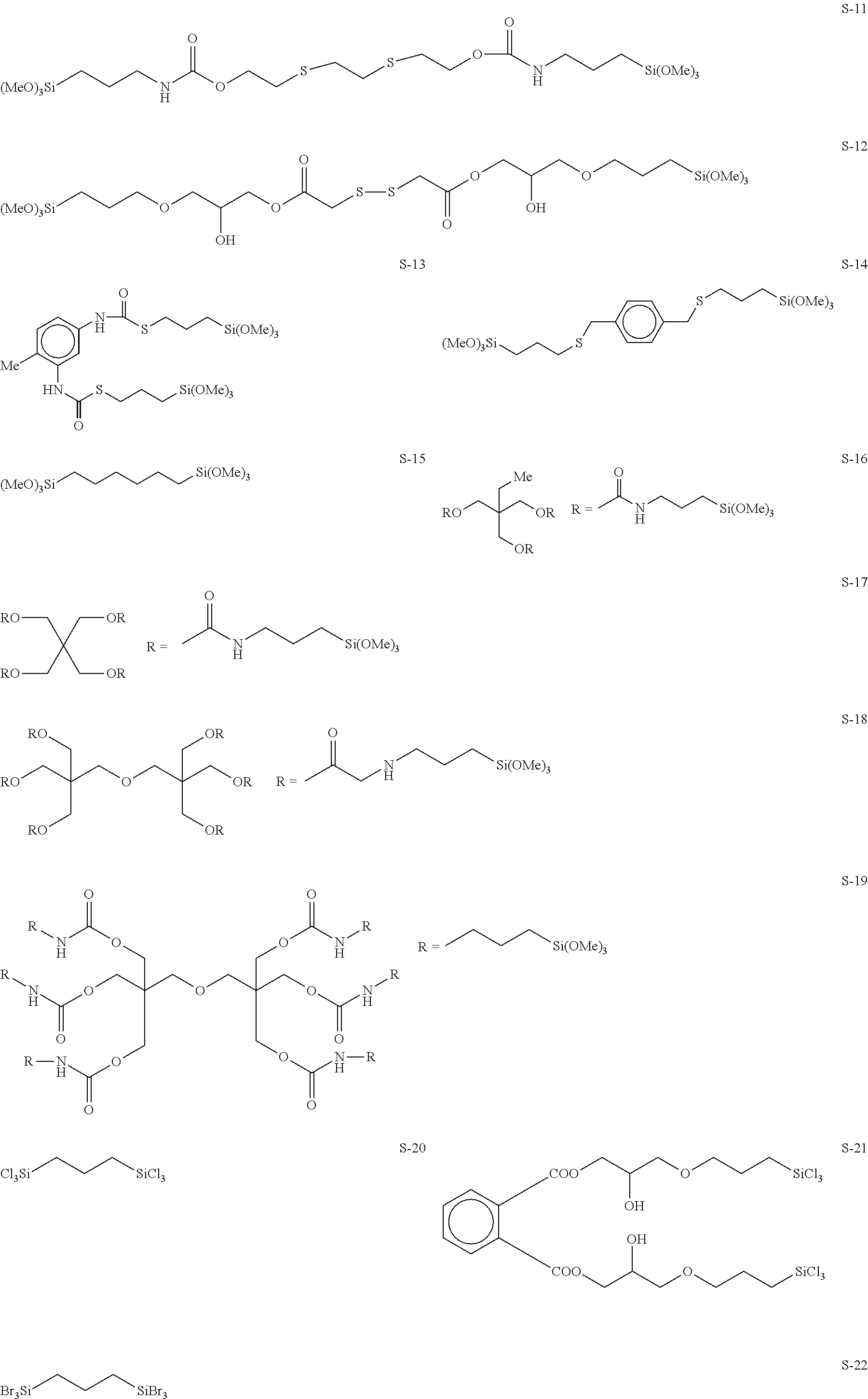

As the crosslinking agent having —SiR¹R²R³, a compound that has been synthesized as appropriate may be employed, but it is preferable to use a commercial product from the viewpoint of cost. These compounds may be purchased as silane compounds or silane coupling agents from Shin-Etsu Chemical Co., Ltd., Dow Corning Toray, etc.

When a compound having —SiR¹R²R³ is used as the crosslinking agent, it is preferable to use a binder polymer having a functional group (e.g. a hydroxy group) that can react therewith, but another binder polymer may be used.

<(3) Crosslinking Agent Having a Plurality of at Least One Group Selected from the Group Consisting of Acid Anhydride Residue, Isocyanate Group, Hydroxy Group, Amino Group, Blocked Isocyanate Group, Carboxy Group, and Epoxy Group>

In the present invention, it is also preferable to use a crosslinking agent having a plurality of at least one group selected from the group consisting of an acid anhydride residue, an isocyanate group, a hydroxy group, an amino group, a blocked isocyanate group, a carboxy group, and an epoxy group. The crosslinking agent having an acid anhydride residue, an isocyanate group, or a hydroxy group is now explained in detail.

### <<Crosslinking Agent Having Acid Anhydride Residue>>

As the crosslinking agent that can be used in the present invention, a crosslinking agent having at least an acid anhydride residue among two or more crosslinkable groups can be cited preferably, a crosslinking agent having two or more acid anhydride residues can be cited more preferably, and a crosslinking agent having two or more carboxylic acid anhydride residues can be cited yet more preferably.

The ‘acid anhydride residue’ referred to in the present invention means an acid anhydride structure formed by dehydration-condensation of two acids present within the same molecule.

As the crosslinking agent having two or more acid anhydride residues used in the present invention, a tetrabasic acid dianhydride can be cited preferably.

Specific examples of the tetrabasic acid dianhydride include an aliphatic or aromatic tetracarboxylic acid dianhydride such as biphenyltetracarboxylic acid dianhydride, naphthalenetetracarboxylic acid dianhydride, diphenyl ether tetracarboxylic acid dianhydride, butanetetracarboxylic acid dianhydride, cyclopentanetetracarboxylic acid dianhydride, pyromellitic dianhydride, benzophenonetetracarboxylic acid dianhydride, or pyridinetetracarboxylic acid dianhydride. Furthermore, as a compound having three carboxylic acid anhydride structures, mellitic acid trianhydride, etc. can be cited.

Specific examples A-1 to A-28 of the crosslinking agent having an acid anhydride residue suitably used in the present invention are given below, but the present invention should not be construed as being limited thereto.

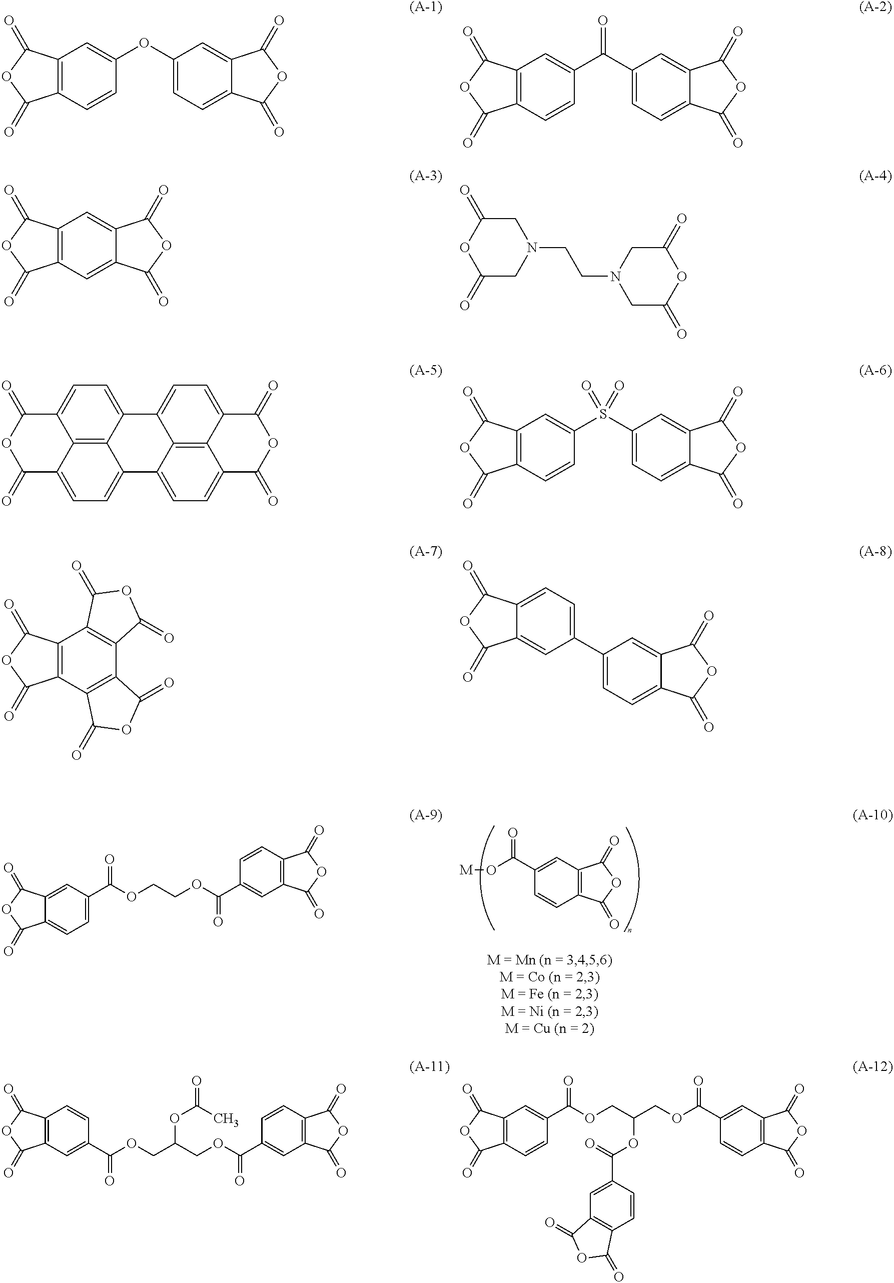

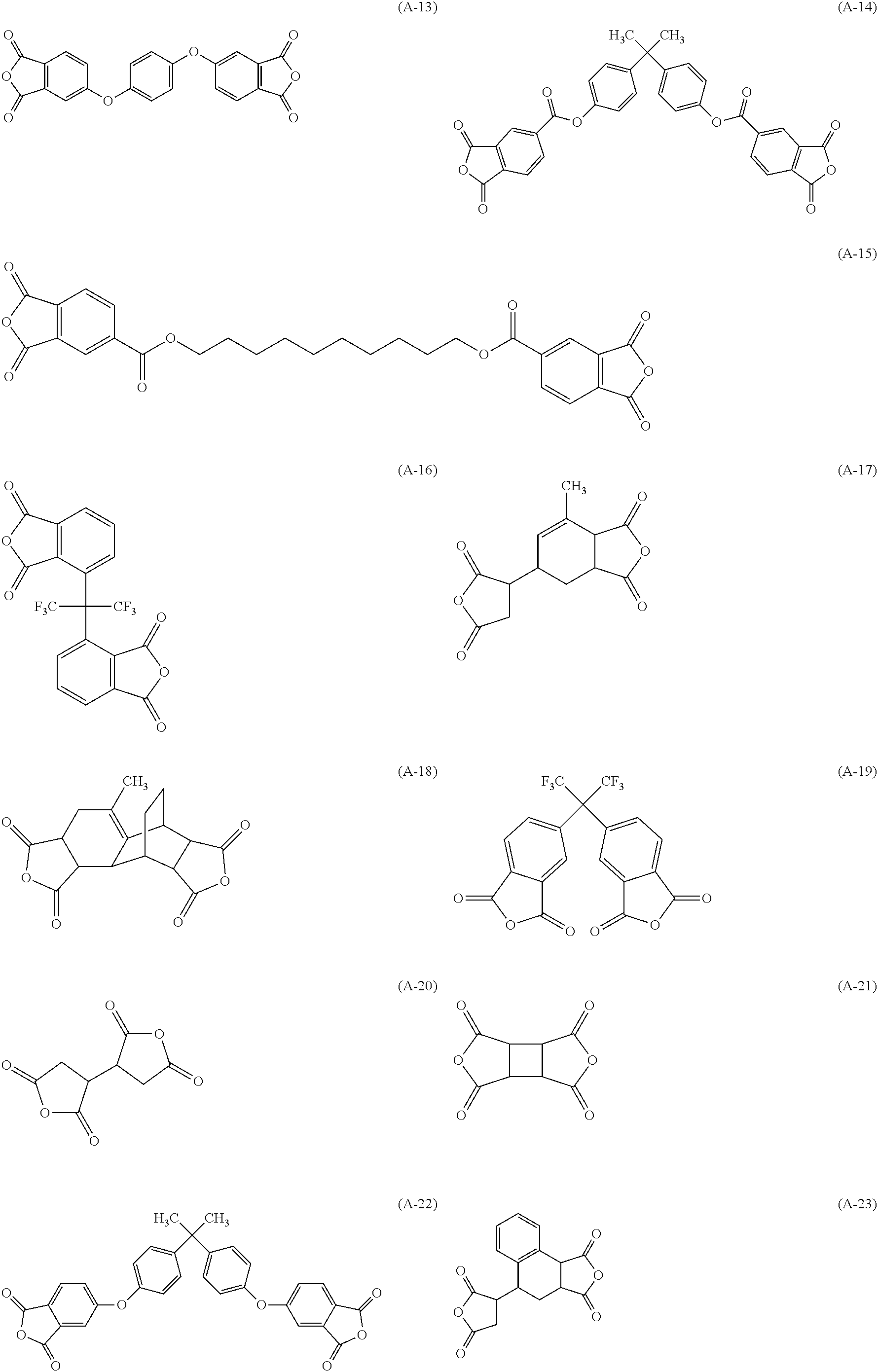

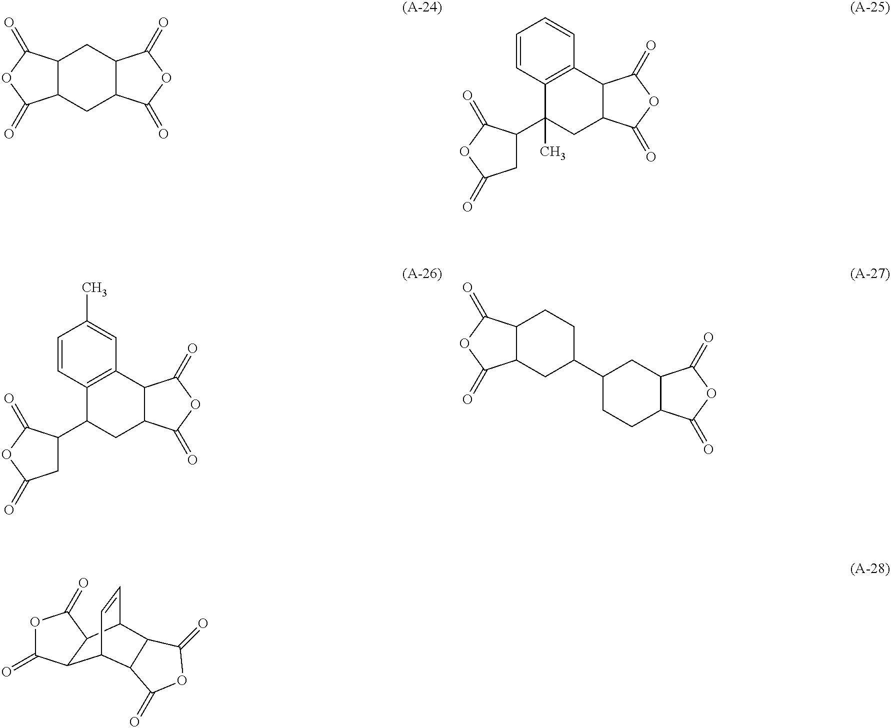

Furthermore, in the crosslinking agent having an acid anhydride residue that can be used in the present invention, examples of commercial products include Rikacid TMGE-S, Rikacid TMGE-100, Rikacid TMGE-200, Rikacid TMGE-500, Rikacid TMGE-600, and Rikacid TMCA-C manufactured by New Japan Chemical Co., Ltd.

### <<Crosslinking Agent Having Isocyanate Group>>

As the crosslinking agent that can be used in the present invention, a crosslinking agent having at least an isocyanate group among two or more crosslinkable groups can be cited preferably, and a crosslinking agent having two or more isocyanate groups can be cited more preferably.

The crosslinking agent having two or more isocyanate groups is not particularly limited as long as it has two or more isocyanate groups, and examples thereof include an aromatic diisocyanate compound, an aliphatic diisocyanate compound, an alicyclic diisocyanate compound, an isocyanurate compound, and a diisocyanate compound that is a reaction product of a diol and a diisocyanate.

Preferred examples of the crosslinking agent having two or more isocyanate groups include diisocyanate compounds represented by Formula (I-1) below.

OCN—X⁰—NCO (I-1)

In Formula (I-1), X⁰ denotes a divalent organic group.

The diisocyanate compound represented by Formula (I-1) above is preferably a diisocyanate compound represented by Formula (I-2) below.

OCN-L¹-NCO (I-2)

In Formula (I-2), L¹ denotes a divalent aliphatic or aromatic hydrocarbon group, which may have a substituent. L¹ may as necessary have another structure or functional group that does not react with an isocyanate group, such as, for example, an ester bond, a urethane bond, an amide bond, and/or a ureido group.

Specific examples of the diisocyanate compound represented by Formula (I-2) above include those shown below.

That is, there can be cited aromatic diisocyanate compounds such as 2,4-tolylene diisocyanate, 2,4-tolylene diisocyanate dimer, 2,6-tolylene diisocyanate, p-xylylene diisocyanate, m-xylylene diisocyanate, 4,4′-diphenylmethane diisocyanate, 1,5-naphthylene diisocyanate, and 3,3′-dimethylbiphenyl-4,4′-diisocyanate; aliphatic diisocyanate compounds such as hexamethylene diisocyanate, trimethylhexamethylene diisocyanate, lysine diisocyanate, and dimer acid diisocyanate; alicyclic diisocyanate compounds such as isophorone diisocyanate, 4,4′-methylenebis(cyclohexyl isocyanate), methylcyclohexane-2,4(or 2,6)-diisocyanate, and 1,3-bis(isocyanatomethyl)cyclohexane; and a diisocyanate compound that is a reaction product of a diisocyanate and a dial such as an adduct between 1 mole of 1,3-butylene glycol and 2 moles of tolylene diisocyanate.

Furthermore, examples of triisocyanate compounds include, but are not limited to, those shown below.

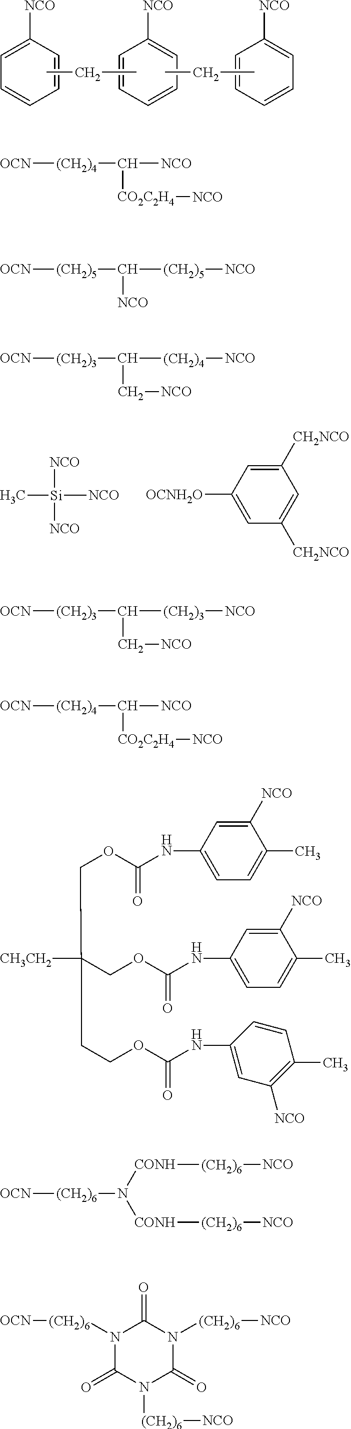

### <<Crosslinking Agent Having Hydroxy Group>>

As the crosslinking agent that can be used in the present invention, a crosslinking agent having, among two or more crosslinkable groups, at least a hydroxy group can be cited preferably, and a crosslinking agent having two or more hydroxy groups can be cited more preferably.

The crosslinking agent having two or more hydroxy groups is not particularly limited as long as it has two or more hydroxy groups, and examples thereof include an aliphatic polyol compound, an alicyclic polyol compound, and an aromatic polyol compound.

The hydroxy group of the crosslinking agent having a hydroxy group may be an alcoholic hydroxy group or a phenolic hydroxy group.

Examples of the crosslinking agent having two or more hydroxy groups include ethylene glycol, diethylene glycol, triethylene glycol, tetraethylene glycol, propylene glycol, neopentyl glycol, 1,3-butylene glycol, 2,2,4-trimethyl-1,3-pentanediol, 1,4-bis-β-hydroxyethoxycyclohexane, cyclohexanedimethanol, tricyclodecanedimethanol, hydrogenated bisphenol A, hydrogenated bisphenol F, bisphenol A ethylene oxide adduct, bisphenol A propylene oxide adduct, bisphenol F ethylene oxide adduct, bisphenol F propylene oxide adduct, hydrogenated bisphenol A ethylene oxide adduct, hydrogenated bisphenol A propylene oxide adduct, hydroquinone dihydroxyethyl ether, p-xylylene glycol, dihydroxyethylsulfone, bis(2-hydroxyethyl)-2,4-tolylene dicarbamate, 2,4-tolylenebis(2-hydroxyethyl carbamide), bis(2-hydroxyethyl)-m-xylylene dicarbamate, bis(2-hydroxyethyl)isophthalate, 1,4-butanediol, 1,5-pentanediol, 1,6-hexanediol, 1,7-heptanediol, 1,8-octanediol, cis-2-butene-1,4-diol, trans-2-butene-1,4-diol, catechol, resorcin, hydroquinone, 4-methylcatechol, 4-t-butylcatechol, 4-acetylcatechol, 3-methoxycatechol, 4-phenylcatechol, 4-methylresorcin, 4-ethylresorcin, 4-t-butylresorcin, 4-hexylresorcin, 4-chlororesorcin, 4-benzylresorcin, 4-acetylresorcin, 4-carbomethoxyresorcin, 2-methylresorcin, 5-methylresorcin, t-butylhydroquinone, 2,5-di-t-butylhydroquinone, 2,5-di-t-amylhydroquinone, tetramethylhydroquinone, tetrachlorohydroquinone, methylcarboaminohydroquinone, methylureidohydroquinone, methylthiohydroquinone, benzonorbornene-3,6-diol, bisphenol A, bisphenol S, 3,3′-dichlorobisphenol S, 4,4′-dihydroxybenzophenone, 4,4′-dihydroxybiphenyl, 4,4′-thiodiphenol, 2,2′-dihydroxydiphenylmethane, 3,4-bis(p-hydroxyphenyl)hexane, 1,4-bis(2-(p-hydroxyphenyl)propyl)benzene, bis(4-hydroxyphenyl)methylamine, 1,3-dihydroxynaphthalene, 1,4-dihydroxynaphthalene, 1,5-dihydroxynaphthalene, 2,6-dihydroxynaphthalene, 1,5-dihydroxyanthraquinone, 2-hydroxybenzyl alcohol, 4-hydroxybenzyl alcohol, 2-hydroxy-3,5-di-t-butylbenzyl alcohol, 4-hydroxy-3,5-di-t-butylbenzyl alcohol, 4-hydroxyphenethyl alcohol, 2-hydroxyethyl-4-hydroxybenzoate, 2-hydroxyethyl-4-hydroxyphenyl acetate, resorcin mono-2-hydroxyethyl ether, pentaethylene glycol, hexaethylene glycol, heptaethylene glycol, octaethylene glycol, di-1,2-propylene glycol, tri-1,2-propylene glycol, tetra-1,2-propylene glycol, hexa-1,2-propylene glycol, di-1,3-propylene glycol, tri-1,3-propylene glycol, tetra-1,3-propylene glycol, di-1,3-butylene glycol, tri-1,3-butylene glycol, and hexa-1,3-butylene glycol.

When the crosslinking agent (3) having a plurality of at least one group selected from the group consisting of an acid anhydride residue, an isocyanate group, a hydroxy group, an amino group, a blocked isocyanate group, a carboxy group, and an epoxy group is used, it is preferable to use a binder polymer having a functional group that can react therewith (e.g. a carboxy group, an amino group, etc.), but another binder polymer may be used.

### <Polymerization Initiator>

In the resin composition for laser engraving of the present invention, when a polymerizable compound is used as the crosslinking agent (c), it is preferable for a polymerization initiator to be contained.

With regard to the polymerization initiator, one known to a person skilled in the art may be used without any limitations. Radical polymerization initiators, which are preferred polymerization initiators, are explained in detail below, but the present invention should not be construed as being limited to these descriptions.

In the present invention, preferred examples of the radical polymerization initiator include (r-a) an aromatic ketone, (r-b) an onium salt compound, (r-c) an organic peroxide, (r-d) a thio compound, (r-e) a hexaarylbiimidazole compound, (r-f) a ketoxime ester compound, (r-g) a borate compound, (r-h) an azinium compound, (r-i) a metallocene compound, (r-j) an active ester compound, (r-k) a compound having a carbon halogen bond, and (r-l) an azo-based compound. Specific examples of (r-a) to (r-l) above are listed below, but the present invention should not be construed as being limited thereto.

In the present invention, from the viewpoint of engraving sensitivity and good relief edge shape being obtained when applied to a relief-forming layer of a relief printing starting plate, an organic peroxide (r-c) and an azo-based compound (r-l) are preferable, and an organic peroxide (r-c) is particularly preferable.

As the aromatic ketone (r-a), onium salt compound (r-b), thio compound (r-d), hexaarylbiimidazole compound (r-e), ketoxime ester compound (r-f), borate compound (r-g), azinium compound (r-h), metallocene compound (r-i), active ester compound (r-j), and compound (r-k) having a carbon halogen bond, compounds described in paragraphs 0074 to 0118 of JP-A-2008-63554 may preferably be used.

Polymerization initiators can be roughly divided into photopolymerization initiators and thermopolymerization initiators.

In the present invention, from the viewpoint of increasing the degree of crosslinking, a thermopolymerization initiator is preferably used.

As the thermopolymerization initiator, the organic peroxide (r-c) and the azo-based compound (r-l) are preferably used. The compounds shown below are particularly preferable.

(r-c) Organic Peroxide

As the organic peroxide (r-c) that can be used in the present invention, peroxyester-based compounds such as 3,3′4,4′-tetra(tert-butylperoxycarbonyl)benzophenone, 3,3′4,4′-tetra(tert-amylperoxycarbonyl)benzophenone, 3,3′4,4′-tetra(tert-hexylperoxycarbonyl)benzophenone, 3,3′4,4′-tetra(tert-octylperoxycarbonyl)benzophenone, 3,3′4,4′-tetra(cumylperoxycarbonyl)benzophenone, 3,3′4,4′-tetra(p-isopropylcumylperoxycarbonyl)benzophenone, and di-tert-butyl diperoxyisophthalate are preferable.

(r-l) Azo-Based Compound

Preferred examples of the azo-based compound (r-l) that can be used in the present invention include 2,2′-azobisisobutyronitrile, 2,2′-azobispropionitrile, 1,1′-azobis(cyclohexane-1-carbonitrile), 2,2′-azobis(2-methylbutyronitrile), 2,2′-azobis(2,4-dimethylvaleronitrile), 2,2′-azobis(4-methoxy-2,4-dimethylvaleronitrile), 4,4′-azobis(4-cyanovaleric acid), dimethyl 2,2′-azobisisobutyrate, 2,2′-azobis(2-methylpropionamidoxime), 2,2′-azobis[2-(2-imidazolin-2-yl)propane], 2,2′-azobis{2-methyl-N-[1,1-bis(hydroxymethyl)-2-hydroxyethyl]propionamide}, 2,2′-azobis[2-methyl-N-(2-hydroxyethyl)propionamide], 2,2′-azobis(N-butyl-2-methylpropionamide), 2,2′-azobis(N-cyclohexyl-2-methylpropionamide), 2,2′-azobis[N-(2-propenyl)-2-methylpropionamide], and 2,2′-azobis(2,4,4-trimethylpentane).

With regard to the polymerization initiator in the present invention, one type may be used on its own or two or more types may be used in combination.

The polymerization initiator may be added preferably at a proportion of 0.01 to 10 wt % relative the total solids content of the resin composition for laser engraving, and more preferably at 0.1 to 3 wt %.

### (d) Crosslinking Promoter

When the above-mentioned ‘compound having —SiR¹R²R³’, etc. is used as a crosslinking agent in the resin composition, in order to promote a reaction between specific hydrophilic compounds or between crosslinking agents or a reaction between a binder polymer and a specific hydrophilic compound or crosslinking agent, it is preferable for a crosslinking promoter (hereinafter, also called a ‘catalyst’) to be contained.

The crosslinking promoter that can be used in the present invention is not particularly limited as long as it is a compound that can promote a reaction between a crosslinking agent and a specific polymer and/or a reaction between a specific hydrophilic compound and a specific polymer, and (1) an acidic catalyst or basic catalyst or (2) a metal complex catalyst may be used.

As the crosslinking promoter, (1) an acidic catalyst or basic catalyst is preferable. Furthermore, when a hydroxy group is involved in a reaction, from the viewpoint of crosslinking speed of the hydroxy group, a basic catalyst is particularly preferable.

### (1) Acidic Catalyst or Basic Catalyst

As the catalyst, an acidic compound or basic compound is used as it is or in the form of a solution in which it is dissolved in a solvent such as water or an organic solvent (hereinafter, also called an acidic catalyst or basic catalyst respectively). The concentration when dissolving in a solvent is not particularly limited, and it may be selected appropriately according to the properties of the acidic compound or basic compound used, desired catalyst content, etc.

The type of acidic catalyst or basic catalyst is not particularly limited; specific examples of the acidic catalyst include a hydrogen halide such as hydrochloric acid, nitric acid, sulfuric acid, sulfurous acid, hydrogen sulfide, perchloric acid, hydrogen peroxide, carbonic acid, a carboxylic acid such as formic acid or acetic acid, a carboxylic acid in which R of the structural formula RCOOH is substituted with another element or substituent, a sulfonic acid such as benzenesulfonic acid, phosphoric acid, a heteropoly acid, and an inorganic solid acid, and examples of the basic catalyst include an ammoniacal base such as aqueous ammonia, an amine such as ethylamine or aniline, an alkali metal hydroxide, an alkali metal alkoxide, an alkaline earth oxide, a quaternary ammonium salt compound, and a quaternary phosphonium salt compound.

Examples of amines are shown below. The amines are

(A-a) a hydrogenated nitrogen compound such as hydrazine;

(A-b) an aliphatic, aromatic, or alicyclic primary, secondary, or tertiary monoamine or polyamine such as a diamine or triamine;

(A-c) a monoamine or polyamine that is a cyclic amine containing a condensed ring and in which at least one nitrogen atom is contained in the ring skeleton;

(A-d) an oxygen-containing amine such as an amino acid, an amide, an alcoholamine, an ether amine, an imide, or a lactam;

(A-e) a heteroelement amine containing a heteroatom such as O, S or Se; etc. When the amine is a secondary or tertiary amine, it may have substituents on the N that are identical to or different from each other or may have one or more different substituents.

Specific examples thereof include hydrazine, a primary amine such as monomethylamine, monoethylamine, a monopropylamine, a monobutylamine, a monopentylamine, a monohexylamine, a monoheptylamine, vinylamine, allylamine, a butenylamine, a pentenylamine, a hexenylamine, a pentadienylamine, a hexadienylamine, cyclopentylamine, cyclohexylamine, cyclooctylamine, p-menthylamine, a cyclopentenylamine, a cyclohexenylamine, a cyclohexadienylamine, aniline, benzylamine, naphthylamine, naphthylmethylamine, toluidine, a tolylenediamine, ethylenediamine, ethylenetriamine, monoethanolamine, aminothiophene, glycine, alanine, phenylalanine, or aminoacetone,

a secondary amine such as dimethylamine, diethylamine, a dipropylamine, a dibutylamine, a dipentylamine, a dihexylamine, methylethylamine, a methylpropylamine, a methylbutylamine, a methylpentylamine, a methylhexylamine, an ethylpropylamine, an ethylbutylamine, an ethylpentylamine, a propylbutylamine, a propylpentylamine, a propylhexylamine, a butylpentylamine, a pentylhexylamine, divinylamine, diallylamine, a dibutenylamine, a dipentenylamine, a dihexenylamine, methylvinylamine, methylallylamine, a methylbutenylamine, a methylpentenylamine, a methylhexenylamine, ethylvinylamine, ethylallylamine, ethylbutenylamine, an ethylpentenylamine, an ethylhexenylamine, a propylvinylamine, a propylallylamine, a propylbutenylamine, a propylpentenylamine, a propylhexenylamine, a butylvinylamine, a butylallylamine, a butylbutenylamine, a butylpentenylamine, a butylhexenylamine, vinylallylamine, a vinylbutenylamine, a vinylpentenylamine, a vinylhexenylamine, an allylbutenylamine, an allylpentenylamine, an allylhexenylamine, a butenylpentenylamine, a butenylhexenylamine, dicyclopentylamine, dicyclohexylamine, methylcyclopentylamine, methylcyclohexylamine, methylcyclooctylamine, ethylcyclopentylamine, ethylcyclohexylamine, ethylcyclooctylamine, a propylcyclopentylamine, a propylcyclohexylamine, a butylcyclopentylamine, a butylcyclohexylamine, a hexylcyclopentylamine, a hexylcyclohexylamine, a hexylcyclooctylamine, vinylcyclopentylamine, vinylcyclohexylamine, vinylcyclooctylamine, allylcyclopentylamine, allylcyclohexylamine, allylcyclooctylamine, a butenylcyclopentylamine, a butenylcyclohexylamine, a butenylcyclooctylamine, a dicyclopentenylamine, a dicyclohexenylamine, a dicyclooctenylamine, a methylcyclopentenylamine, a methylcyclohexenylamine, a methylcyclooctenylamine, an ethylcyclopentenylamine, an ethylcyclohexenylamine, an ethylcyclooctenylamine, a propylcyclopentenylamine, a propylcyclohexenylamine, a butylcyclopentenylamine, a butylcyclohexenylamine, a vinylcyclopentenylamine, a vinylcyclohexenylamine, a vinylcyclooctenylamine, an allylcyclopentenylamine, an allylcyclohexenylamine, a butenylcyclopentenylamine, a butenylcyclohexenylamine,

dicyclopentadienylamine, a dicyclohexadienylamine, a dicyclooctadienylamine, methylcyclopentadienylamine, a methylcyclohexadienylamine, ethylcyclopentadienylamine, an ethylcyclohexadienylamine, a propylcyclopentadienylamine, a propylcyclohexadienylamine, a dicyclooctatrienylamine, a methylcyclooctatrienylamine, an ethylcyclooctatrienylamine, vinylcyclopentadienylamine, a vinylcyclohexadienylamine, allylcyclopentadienylamine, an allylcyclohexadienylamine, diphenylamine, a ditolylamine, dibenzylamine, a dinaphthylamine, N-methylaniline, N-ethylaniline, an N-propylaniline, an N-butylaniline, N-methyltoluidine, N-ethyltoluidine, an N-propyltoluidine, an N-butyltoluidine, N-methylbenzylamine, an N-ethylbenzylamine, an N-propylbenzylamine, an N-butylbenzylamine, an N-methylnaphthylamine, an N-ethylnaphthylamine, an N-propylnaphthylamine, N-vinylaniline, N-allylaniline, N-vinylbenzylamine, N-allylbenzylamine, N-vinyltoluidine, N-allyltoluidine, phenylcyclopentylamine, phenylcyclohexylamine, phenylcyclooctylamine, phenylcyclopentenylamine, phenylcyclohexenylamine, phenylcyclopentadienylamine, N-methylanisole, N-ethylanisole, N-vinylanisole, N-allylanisole, N-methylethylenediamine, N,N′-dimethylethylenediamine, N-ethylethylenediamine, N,N′-diethylethylenediamine, an N,N′-dimethyltolylenediamine, an N,N′-diethyltolylenediamine, N-methylethylenetriamine, N,N′-dimethylethylenetriamine, pyrrole, pyrrolidine, imidazole, piperidine, piperazine, a methylpyrrole, a methylpyrrolidine, a methylimidazole, a methylpiperidine, a methylpiperazine, an ethylpyrrole, an ethylpyrrolidine, an ethylimidazole, an ethylpiperidine, an ethylpiperazine, phthalimide, maleimide, caprolactam, pyrrolidone, morpholine, N-methylglycine, N-ethylglycine, N-methylalanine, N-ethylalanine, N-methylaminothiophene, N-ethylaminothiophene, 2,5-piperazinedione, N-methylethanolamine, N-ethylethanolamine, or purine, and

a tertiary amine such as trimethylamine, triethylamine, a tripropylamine, a tributylamine, a tripentylamine, a trihexylamine, dimethylethylamine, a dimethylpropylamine, a dimethylbutylamine, a dimethylpentylamine, a dimethylhexylamine, a diethylpropylamine, a diethylbutylamine, a diethylpentylamine, a diethylhexylamine, a dipropylbutylamine, a dipropylpentylamine, a dipropylhexylamine, a dibutylpentylamine, a dibutylhexylamine, a dipentylhexylamine, methyldiethylamine, a methyldipropylamine, a methyldibutylamine, a methyldipentylamine, a methyldihexylamine, an ethyldipropylamine, an ethyldibutylamine, an ethyldipentylamine, an ethyldihexylamine, a propyldibutylamine, a propyldipentylamine, a propyldihexylamine, a butyldipentylamine, a butyldihexylamine, a pentyldihexylamine, a methylethylpropylamine, a methylethylbutylamine, a methylethylhexylamine, a methylpropylbutylamine, a methylpropylhexylamine, ethylpropylbutylamine, an ethylbutylpentylamine, an ethylbutylhexylamine, a propylbutylpentylamine, a propylbutylhexylamine, a butylpentylhexylamine, trivinylamine, triallylamine, a tributenylamine, a tripentenylamine, a trihexenylamine,

dimethylvinylamine, dimethylallylamine, a dimethylbutenylamine, a dimethylpentenylamine, diethylvinylamine, diethylallylamine, a diethylbutenylamine, a diethylpentenylamine, a diethylhexenylamine, a dipropylvinylamine, a dipropylallylamine, a dipropylbutenylamine, methyldivinylamine, methyldiallylamine, a methyldibutenylamine, ethyldivinylamine, ethyldiallylamine, tricyclopentylamine, tricyclohexylamine, tricyclooctylamine, tricyclopentenylamine, tricyclohexenylamine, tricyclopentadienylamine, a tricyclohexadienylamine, dimethylcyclopentylamine, diethylcyclopentylamine, a dipropylcyclopentylamine, a dibutylcyclopentylamine, dimethylcyclohexylamine, diethylcyclohexylamine, a dipropylcyclohexylamine, a dimethylcyclopentenylamine, a diethylcyclopentenylamine, a dipropylcyclopentenylamine, a dimethylcyclohexenylamine, a diethylcyclohexenylamine, a dipropylcyclohexenylamine, methyldicyclopentylamine, ethyldicyclopentylamine, a propylcyclopentylamine, methyldicyclohexylamine, ethyldicyclohexylamine, a propylcyclohexylamine, a methyldicyclopentenylamine, an ethyldicyclopentenylamine, a propyldicyclopentenylamine, N,N-dimethylaniline, N,N-dimethylbenzylamine, an N,N-dimethyltoluidine, an N,N-dimethylnaphthylamine, N,N-diethylaniline, N,N-diethylbenzylamine, an N,N-diethyltoluidine, an N,N-diethylnaphthylamine, an N,N-dipropylaniline, an N,N-dipropylbenzylamine, an N,N-dipropyltoluidine, an N,N-dipropylnaphthylamine,

N,N-divinylaniline, N,N-diallylaniline, an N,N-divinyitoluidine, N,N-diallylaniline, diphenylmethylamine, diphenylethylamine, a diphenylpropylamine, dibenzylmethylamine, dibenzylethylamine, dibenzylcyclohexylamine, dibenzylvinylamine, dibenzylallylamine, a ditolylmethylamine, a ditolylethylamine, a ditolylcyclohexylamine, a ditolylvinylamine, triphenylamine, tribenzylamine, a tri(tolyl)amine, a trinaphthylamine, N,N,N′,′-tetramethylethylenediamine, N,N,N′,N′-tetraethylethylenediamine, an N,N,N′,N′-tetramethyltolylenediamine, an N,N,N′,N′-tetraethyltolylenediamine, N-methylpyrrole, N-methylpyrrolidine, N-methylimidazole, N,N′-dimethylpiperazine, N-methylpiperidine, N-ethylpyrrole, N-methylpyrrolidine, N-ethylimidazole, N,N′-diethylpiperazine, N-ethylpiperidine, pyridine, pyridazine, pyrazine, quinoline, quinazoline, quinuclidine, N-methylpyrrolidone, N-methylmorpholine, N-ethylpyrrolidone, N-ethylmorpholine, N,N-dimethylanisole, N,N-diethylanisole, N,N-dimethylglycine, N,N-diethylglycine, N,N-dimethylalanine, N,N-diethylalanine, N,N-dimethylethanolamine, N,N-dimethylaminothiophene, 1,1,3,3-tetramethylguanidine, 1,8-diazabicyclo[5.4.0]undec-7-ene, 1,5-diazabicyclo[4.3.0]non-5-ene, 1,4-diazabicyclo[2.2.2]octane, or hexamethylenetetramine.

Therefore, the above-mentioned amine is a compound in which an aliphatic or alicyclic saturated or unsaturated hydrocarbon group, an aromatic hydrocarbon group, an oxygen-containing, sulfur-containing, and/or selenium-containing hydrocarbon group, etc. is bonded to one or more nitrogen atoms. From the viewpoint of film strength after thermal crosslinking, the pKa (acid dissociation constant of conjugated acid) range of the amine is preferably 7 or greater, and more preferably 10 or greater.

From the viewpoint of an alcohol exchange reaction in the film progressing promptly, methanesulfonic acid, p-toluenesulfonic acid, pyridinium p-toluenesulfonate, dodecylbenzenesulfonic acid, phosphoric acid, phosphonic acid, acetic acid, 1,8-diazabicyclo[5.4.0]undec-7-ene, 1,5-diazabicyclo[4.3.0]non-5-ene, and 1,1,3,3-tetramethylguanidine are preferable, and methanesulfonic acid, p-toluenesulfonic acid, phosphoric acid, 1,8-diazabicyclo[5.4.0]undec-7-ene, and 1,5-diazabicyclo[4.3.0]non-5-ene are particularly preferable.

### (2) Metal Complex Catalyst

The metal complex catalyst that can be used in the present invention is preferably a metal complex catalyst formed from a metal element selected from the group consisting of Groups 2, 4, 5, and 13 of the periodic table and an oxo or hydroxy oxygen-containing compound selected from the group consisting of β-diketones, ketoesters, hydroxycarboxylic acids and esters thereof, amino alcohols, and enolic active hydrogen compounds.

Furthermore, among the constituent metal elements, a Group 2 element such as Mg, Ca, Sr, or Ba, a Group 4 element such as Ti or Zr, a Group 5 element such as V, Nb, or Ta, and a Group 13 element such as Al or Ga are preferable, and they form a complex having an excellent catalytic effect. Among them, a complex obtained from Zr, Al, or Ti (ethyl orthotitanate, etc.) is excellent and preferable.

Examples of the oxo or hydroxy oxygen-containing compound forming a ligand of the above-mentioned metal complex include β-diketones such as acetylacetone (2,4-pentanedione) and 2,4-heptanedione, ketoesters such as methyl acetoacetate, ethyl acetoacetate, and butyl acetoacetate, hydroxycarboxylic acids and esters thereof such as lactic acid, methyl lactate, salicylic acid, ethyl salicylate, phenyl salicylate, malic acid, tartaric acid, and methyl tartarate, ketoalcohols such as 4-hydroxy-4-methyl-2-pentanone, 4-hydroxy-2-pentanone, 4-hydroxy-4-methyl-2-heptanone, and 4-hydroxy-2-heptanone, amino alcohols such as monoethanolamine, N,N-dimethylethanolamine, N-methylmonoethanolamine, diethanolamine, and triethanolamine, enolic active compounds such as methylolmelamine, methylolurea, methylolacrylamide, and diethyl malonate ester, and compounds having a substituent on the methyl group, methylene group, or carbonyl carbon of acetylacetone.

A preferred ligand is acetylacetone or an acetylacetone derivative.

The acetylacetone derivative in the present invention means a compound having a substituent on the methyl group, methylene group, or carbonyl carbon of acetylacetone. The substituent with which the methyl group of acetylacetone is substituted is a straight chain or branched alkyl group, acyl group, hydroxyalkyl group, carboxyalkyl group, alkoxy group, or alkoxyalkyl group having 1 to 3 carbon atoms.

The substituent with which the methylene carbon of acetylacetone is substituted is a carboxy group or a straight chain or branched carboxyalkyl group or hydroxyalkyl group having 1 to 3 carbon atoms, and the substituent with which the carbonyl carbon of acetylacetone is substituted is an alkyl group having 1 to 3 carbon atoms, and in this case the carbonyl oxygen turns into a hydroxy group by addition of a hydrogen atom.

Specific preferred examples of the acetylacetone derivative include ethylcarbonylacetone, n-propylcarbonylacetone, i-propylcarbonylacetone, diacetylacetone, 1-acetyl-1-propionylacetylacetone, hydroxyethylcarbonylacetone, hydroxypropylcarbonylacetone, acetoacetic acid, acetopropionic acid, diacetoacetic acid, 3,3-diacetopropionic acid, 4,4-diacetobutyric acid, carboxyethylcarbonylacetone, carboxypropylcarbonylacetone, and diacetone alcohol.

Among them, as a ligand, acetylacetone and diacetylacetone are particularly preferable.

The complex of the acetylacetone or acetylacetone derivative and the metal element is preferably a mononuclear complex in which 1 to 4 molecules of acetylacetone or acetylacetone derivative coordinate to one metal element, and when the number of coordinatable sites of the metal element is larger than the total number of coordinatable bond sites of the acetylacetone or acetylacetone derivative, a ligand that is usually used in a normal complex, such as a water molecule, a halide ion, a nitro group, or an ammonia group may coordinate thereto.

Preferred examples of the metal complex include a tris(acetylacetonato)aluminum complex salt, a di(acetylacetonato)aluminum-aqua complex salt, a mono(acetylacetonato)aluminum-chloro complex salt, a di(diacetylacetonato)aluminum complex salt, ethyl acetoacetate aluminum diisopropylate, aluminum tris(ethyl acetoacetate), cyclic aluminum oxide isopropylate, a tris(acetylacetonato)barium complex salt, a di(acetylacetonato)titanium complex salt, a tris(acetylacetonato)titanium complex salt, a di-i-propoxy-bis(acetylacetonato)titanium complex salt, zirconium tris(ethyl acetoacetate), and a zirconium tris(benzoic acid) complex salt. They are excellent in terms of stability in an aqueous coating solution and an effect in promoting gelling in a sol-gel reaction when thermally drying, and among them ethyl acetoacetate aluminum diisopropylate, aluminum tris(ethyl acetoacetate), a di(acetylacetonato)titanium complex salt, and zirconium tris(ethyl acetoacetate) are particularly preferable.

The resin composition may employ only one type of crosslinking promoter or two or more types thereof in combination.

The content of the crosslinking promoter in the resin composition is preferably 0.01 to 20 parts by weight relative to 100 parts by weight of the specific polymer (a), and more preferably 0.1 to 10 parts by weight.

### (e) Photothermal Conversion Agent

The resin composition for laser engraving of the present invention preferably comprises (e) a photothermal conversion agent.

It is surmised that the photothermal conversion agent absorbs laser light and generates heat thus promoting thermal decomposition of a cured material of the resin composition for laser engraving of the present invention. Because of this, it is preferable to select a photothermal conversion agent that absorbs light having the wavelength of the laser that is used for engraving.

When a laser (a YAG laser, a semiconductor laser, a fiber laser, a surface emitting laser, etc.) emitting infrared at a wavelength of 700 nm to 1,300 nm is used as a light source for laser engraving, it is preferable for the relief-forming layer in the present invention to comprise a photothermal conversion agent that can absorb light having a wavelength of 700 nm to 1,300 nm.

As the photothermal conversion agent in the present invention, various types of dye or pigment are used.

With regard to the photothermal conversion agent, examples of dyes that can be used include commercial dyes and known dyes described in publications such as ‘Senryo Binran’ (Dye Handbook) (Ed. by The Society of Synthetic Organic Chemistry, Japan, 1970). Specific examples include dyes having a maximum absorption wavelength at 700 nm to 1,300 nm, such as azo dyes, metal complex salt azo dyes, pyrazolone azo dyes, naphthoquinone dyes, anthraquinone dyes, phthalocyanine dyes, carbonium dyes, diimmonium compounds, quinone imine dyes, methine dyes, cyanine dyes, squarylium dyes, pyrylium salts, and metal thiolate complexes. In particular, cyanine-based dyes such as heptamethine cyanine dyes, oxonol-based dyes such as pentamethine oxonol dyes, and phthalocyanine-based dyes are preferably used. Examples include dyes described in paragraphs 0124 to 0137 of JP-A-2008-63554.

With regard to the photothermal conversion agent used in the present invention, examples of pigments include commercial pigments and pigments described in the Color Index (C.I.) Handbook, ‘Saishin Ganryo Binran’ (Latest Pigments Handbook) (Ed. by Nippon Ganryo Gijutsu Kyokai, 1977), ‘Saisin Ganryo Ouyogijutsu’ (Latest Applications of Pigment Technology) (CMC Publishing, 1986), ‘Insatsu Inki Gijutsu’ (Printing Ink Technology) CMC Publishing, 1984).

Examples of the type of pigment include black pigments, yellow pigments, orange pigments, brown pigments, red pigments, violet pigments, blue pigments, green pigments, fluorescent pigments, metal powder pigments, and other polymer-bonding colorants. Specific examples include insoluble azo pigments, azo lake pigments, condensed azo pigments, chelate azo pigments, phthalocyanine-based pigments, anthraquinone-based pigments, perylene and perinone-based pigments, thioindigo-based pigments, quinacridone-based pigments, dioxazine-based pigments, isoindolinone-based pigments, quinophthalone-based pigments, dyed lake pigments, azine pigments, nitroso pigments, nitro pigments, natural pigments, fluorescent pigments, inorganic pigments, and carbon black. Among these pigments, carbon black is preferable.

Any carbon black, regardless of classification by ASTM and application (e.g. for coloring, for rubber, for dry cell, etc.), may be used as long as dispersibility, etc. in the composition is stable. Carbon black includes for example furnace black, thermal black, channel black, lamp black, and acetylene black. In order to make dispersion easy, a black colorant such as carbon black may be used as color chips or a color paste by dispersing it in nitrocellulose or a binder in advance using, as necessary, a dispersant, and such chips and paste are readily available as commercial products.

In the present invention, it is possible to use carbon black having a relatively low specific surface area and a relatively low dibutyl phthalate (DBP) absorption and also finely divided carbon black having a large specific surface area. Preferred examples of carbon black include Printex (registered trademark) U, Printex (registered trademark) A, and Spezialschwarz (registered trademark) 4 (Degussa).

From the viewpoint of improving engraving sensitivity by efficiently transmitting heat generated by photothermal conversion to the surrounding polymer, etc., the carbon black that can be used in the present invention is preferably a conductive carbon black having a specific surface area of at last 150 m²/g and a DBP number of at least 150 mL/100 g.

This specific surface area is preferably at least 250 m²/g, and particularly preferably at least 500 m²/g. The DBP number is preferably at least 200 mL/100 g, and particularly preferably at least 250 mL/100 g. The above-mentioned carbon black may be acidic or basic carbon black. The carbon black is preferably basic carbon black. It is of course possible to use a mixture of different carbon blacks.

Conductive carbon black having a specific surface area of 150 to about 1,500 m²/g and a DBP number of 150 to about 550 mL/100 g is commercially available under names such as for example Ketjenblack (registered trademark) EC300J, Ketjenblack (registered trademark) EC600J (Akzo), Printex (registered trademark) XE (Degussa), Black Pearls (registered trademark) 2000 (Cabot), and Ketjen Black (Lion Corporation).

The content of the photothermal conversion agent in the resin composition for laser engraving of the present invention largely depends on the size of the molecular extinction coefficient characteristic to the molecule, and is preferably 0.01 to 20 wt % relative to the total weight of the solids content of the resin composition, more preferably 0.05 to 10 wt %, and yet more preferably 0.1 to 5 wt %.

### (f) Solvent

The resin composition of the present invention may comprise a solvent for promoting a reaction between the specific polymer and the specific hydrophilic compound or a reaction between the specific polymer and the crosslinking agent, adjustment of the viscosity of the resin composition, and making relief-forming layer formation such as coating, casting, etc. easy. The solids content of the resin composition means the amount excluding volatile components such as solvent.

From the viewpoint of making a reaction between the specific polymer and the specific hydrophilic compound or a reaction between the specific polymer and the crosslinking agent progress promptly, the solvent is preferably used at aprotic organic solvent/protic organic solvent=100/0 to 50/50 (ratio by weight), more preferably 100/0 to 70/30, and yet more preferably 100/0 to 90/10.

Specific preferred examples of the aprotic organic solvent include acetonitrile, tetrahydrofuran, dioxane, toluene, propylene glycol monomethyl ether acetate, methyl ethyl ketone, acetone, methyl isobutyl ketone, ethyl acetate, butyl acetate, ethyl lactate, N,N-dimethylacetamide, N-methylpyrrolidone, and dimethyl sulfoxide.

Specific preferred examples of the protic organic solvent include methanol, ethanol, 1-propanol, 2-propanol, 1-butanol, 1-methoxy-2-propanol, ethylene glycol, diethylene glycol, and 1,3-propanediol.

### (g) Other Additives

The resin composition for laser engraving of the present invention preferably comprises a plasticizer.

The plasticizer has the function of softening a film formed from the resin composition for laser engraving and is required to be compatible with a binder polymer.

Examples of the plasticizer that are preferably used include dioctyl phthalate, didodecyl phthalate, a polyethylene glycol, and polypropylene glycol (monool type or diol type).

The resin composition for laser engraving of the present invention preferably comprises, as an additive for improving engraving sensitivity, nitrocellulose or a high thermal conductivity material. Since nitrocellulose is a self-reactive compound, it generates heat during laser engraving, thus assisting thermal decomposition of a coexisting binder polymer such as a hydrophilic polymer. It is surmised that as a result, the engraving sensitivity improves. A high thermal conductivity material is added for the purpose of assisting heat transfer, and examples of thermally conductive materials include inorganic compounds such as metal particles and organic compounds such as a conductive polymer. As the metal particles, fine gold particles, fine silver particles, and fine copper particles having a particle diameter of on the order of a micrometer or a few nanometers are preferable. As the conductive polymer, a conjugated polymer is particularly preferable, and specific examples thereof include polyaniline and polythiophene.

For the purpose of coloring the resin composition for laser engraving, a colorant such as a dye or a pigment may be added. This enables properties such as visibility of an image area or suitability for an image densitometer to be improved.

Furthermore, in order to improve physical properties of a cured film of the resin composition for laser engraving, a known additive such as a filler may be added.

### (Relief Printing Starting Plate for Laser Engraving)

A first embodiment of the relief printing starting plate for laser engraving of the present invention comprises a relief-forming layer formed from the resin composition for laser engraving of the present invention.

A second embodiment of the relief printing starting plate for laser engraving of the present invention comprises a crosslinked relief-forming layer formed by crosslinking a relief-forming layer formed from the resin composition for laser engraving of the present invention.

In the present invention, the ‘relief printing starting plate for laser engraving’ means both or one of a plate having a crosslinkable relief-forming layer formed from the resin composition for laser engraving in a state before being crosslinked and a plate in a state in which it is cured by light or heat.

In the present invention, the ‘relief-forming layer’ means a layer in a state before being crosslinked, that is, a layer formed from the resin composition for laser engraving of the present invention, which may be dried as necessary.

In the present invention, the ‘crosslinked relief-forming layer’ means a layer formed by crosslinking the relief-forming layer. The crosslinking is preferably carried out by means of heat and/or light. Furthermore, the crosslinking is not particularly limited as long as it is a reaction by which the resin composition is cured, and it is a concept that includes a structure crosslinked due to reactions between specific hydrophilic compounds and between crosslinking agents, but it is preferable to form a crosslinked structure by a reaction between the hydrophilic compound and crosslinking agent and the polymer.

The ‘relief printing plate’ is prepared by laser engraving a printing starting plate having a crosslinked relief-forming layer.

Moreover, in the present invention, the ‘relief layer’ means a layer of the relief printing plate formed by engraving using a laser, that is, the crosslinked relief-forming layer after laser engraving.

The relief-forming layer is preferably provided above a support.

The relief printing starting plate for laser engraving may further comprise, as necessary, an adhesive layer between the support and the relief-forming layer and, above the relief-forming layer, a slip coat layer and a protection film.

### <Relief-Forming Layer>

The relief-forming layer is a layer formed from the resin composition for laser engraving of the present invention, and is preferably a layer that is cured by at least one of light and heat, that is, a layer having crosslinkability.

As a process for producing a relief printing plate using the relief printing starting plate of the present invention, it is preferably a process for producing a relief printing plate by crosslinking a relief-forming layer and then carrying out laser engraving to thus form a relief layer. By crosslinking the relief-forming layer, it is possible to prevent abrasion of the relief layer during printing, and it is possible to obtain a relief printing plate having a relief layer with a sharp shape after laser engraving.

In addition, the relief-forming layer may be formed by molding the resin composition for laser engraving into a sheet shape or a sleeve shape.

### <Support>

The support that can be used in the relief printing starting plate for laser engraving is now explained.

A material used for the support of the relief printing starting plate for laser engraving is not particularly limited, but one having high dimensional stability is preferably used, and examples thereof include metals such as steel, stainless steel, or aluminum, plastic resins such as a polyester (e.g. polyethylene terephthalate (PET) or polybutylene terephthalate (PBT)), polyacrylonitrile (PAN) or polyvinyl chloride, synthetic rubbers such as styrene-butadiene rubber, and glass fiber-reinforced plastic resins (epoxy resin, phenolic resin, etc.). As the support, a PET film or a steel substrate is preferably used. The configuration of the support depends on whether the relief-forming layer is in a sheet shape or a sleeve shape.

Furthermore, in a relief printing starting plate for laser engraving prepared by coating a crosslinkable resin composition for laser engraving and curing it from the reverse face (face opposite to the face that is to be subjected to laser engraving, those with a cylindrical shape also being included) by means of heat and/or light, the reverse face of the cured resin composition for laser engraving functions as a support, and a support is therefore not always necessary.

### <Adhesive Layer>

An adhesive layer may be provided between the relief-forming layer and the support for the purpose of strengthening the adhesion between the two layers. Examples of materials (adhesives) that can be used in the adhesive layer include those described in ‘Handbook of Adhesives’, Second Edition, Ed by I. Skeist, (1977).

### <Protection Film, Slip Coat Layer>

For the purpose of preventing scratches or dents in the relief-forming layer surface or the crosslinked relief-forming layer surface, a protection film may be provided on the relief-forming layer surface or the crosslinked relief-forming layer surface. The thickness of the protection film is preferably 25 to 500 μm, and more preferably 50 to 200 μm. The protection film may employ, for example, a polyester-based film such as PET or a polyolefin-based film such as PE (polyethylene) or PP (polypropylene). The surface of the film may be made matte. The protection film is preferably peelable.

When the protection film is not peelable or conversely has poor adhesion to the relief-forming layer, a slip coat layer may be provided between the two layers. The material used in the slip coat layer preferably employs as a main component a resin that is soluble or dispersible in water and has little tackiness, such as polyvinyl alcohol, polyvinyl acetate, partially saponified polyvinyl alcohol, a hydroxyalkylcellulose, an alkylcellulose, or a polyamide resin.

### (Process for Producing Relief Printing Starting Plate for Laser Engraving)

The process for producing a relief printing starting plate for laser engraving is now explained.

Formation of a relief-forming layer in the relief printing starting plate for laser engraving is not particularly limited, and examples thereof include a method in which the resin composition for laser engraving is prepared, solvent is removed from this coating solution composition for laser engraving, and it is melt-extruded onto a support. Alternatively, a method may be employed in which the coating solution composition for laser engraving is cast onto a support, and this is dried in an oven to thus remove solvent from the coating solution composition.

Among them, the process for producing a relief printing starting plate for laser engraving of the present invention is preferably a production process comprising a layer formation step of forming a relief-forming layer from the resin composition for laser engraving of the present invention and a crosslinking step of crosslinking the relief-forming layer by means of heat and/or light to thus obtain a relief printing starting plate having a crosslinked relief-forming layer.

Subsequently, as necessary, a protection film may be laminated on the relief-forming layer. Laminating may be carried out by compression-bonding the protection film and the relief-forming layer by means of heated calendar rollers, etc. or putting a protection film into intimate contact with a relief-forming layer whose surface is impregnated with a small amount of solvent.

When a protection film is used, a method in which a relief-forming layer is first layered on a protection film and a support is then laminated may be employed.

When an adhesive layer is provided, it may be dealt with by use of a support coated with an adhesive layer. When a slip coat layer is provided, it may be dealt with by use of a protection film coated with a slip coat layer.

### <Layer Formation Step>

The process for producing the relief printing starting plate for laser engraving of the present invention preferably comprises a layer formation step of forming a relief-forming layer from the resin composition for laser engraving of the present invention.

Preferred examples of a method for forming a relief-forming layer include a method in which the resin composition for laser engraving of the present invention is prepared, solvent is removed as necessary from this resin composition for laser engraving, and it is then melt-extruded onto a support and a method in which the resin composition for laser engraving of the present invention is prepared, the resin composition for laser engraving of the present invention is cast onto a support, and this is dried in an oven to thus remove the solvent.

The resin composition for laser engraving may be produced by, for example, dissolving the crosslinking agent, the polymer, a fragrance, and as optional components a photothermal conversion agent and a plasticizer in an appropriate solvent, and then dissolving a polymerizable compound and a polymerization initiator. Since it is necessary to remove most of the solvent component in a stage of producing a relief printing starting plate, it is preferable to use as the solvent a volatile low-molecular-weight alcohol (e.g. methanol, ethanol, n-propanol, isopropanol, propylene glycol monomethyl ether), etc., and adjust the temperature, etc. to thus reduce as much as possible the total amount of solvent to be added.

The thickness of the relief-forming layer in the relief printing starting plate for laser engraving before and after crosslinking is preferably at least 0.05 mm but no greater than 10 mm, more preferably at least 0.05 mm but no greater than 7 mm, and yet more preferably at least 0.05 mm but no greater than 3 mm.

### <Crosslinking Step>

The process for producing a relief printing starting plate for laser engraving of the present invention is preferably a production process comprising a crosslinking step of crosslinking the relief-forming layer by means of heat and/or light to thus obtain a relief printing starting plate having a crosslinked relief-forming layer.

With regard to irradiation with light, it is preferable to carry it out for the entire surface of the relief-forming layer.

Examples of the light include visible light, UV light, and an electron beam, and UV light is most preferable. When the support side of the relief-forming layer is defined as the reverse face, only the front face need be irradiated with light, but when the support is a transparent film through which light passes, it is preferable to further irradiate the reverse face with light as well. When a protection film is present, irradiation from the front face may be carried out with the protection film as it is or after peeling off the protection film. When there is a possibility of a crosslinking reaction being inhibited in the presence of oxygen, irradiation with light may be carried out after superimposing a polyvinyl chloride sheet on the relief-forming layer and evacuating.

When the relief-forming layer comprises a thermopolymerization initiator (the above-mentioned photopolymerization initiator being capable of functioning also as a thermopolymerization initiator), the relief-forming layer may be crosslinked by heating the relief printing starting plate for laser engraving (step of crosslinking by means of heat). As heating means for carrying out crosslinking by heat, there can be cited a method in which a printing starting plate is heated in a hot air oven or an infrared oven for a predetermined period of time and a method in which it is put into contact with a heated roller for a predetermined period of time.

As a method for crosslinking the relief-forming layer in the crosslinking step, from the viewpoint of the relief-forming layer being uniformly curable (crosslinkable) from the surface into the interior, crosslinking by heat is preferable.

Due to the relief-forming layer being crosslinked, firstly, a relief formed after laser engraving becomes sharp and, secondly, the tackiness of engraving residue formed when laser engraving is suppressed.

### (Relief Printing Plate and Process for Making Same)

The process for making a relief printing plate of the present invention comprises a layer formation step of forming a relief-forming layer from the resin composition for laser engraving of the present invention, a crosslinking step of crosslinking the relief-forming layer by means of heat and/or light to thus obtain a relief printing starting plate having a crosslinked relief-forming layer, and an engraving step of laser-engraving the relief printing starting plate having the crosslinked relief-forming layer.

The relief printing plate of the present invention is a relief printing plate having a relief layer obtained by crosslinking and laser-engraving a layer formed from the resin composition for laser engraving of the present invention, and is preferably a relief printing plate made by the process for making a relief printing plate of the present invention.

The layer formation step and the crosslinking step in the process for making a relief printing plate of the present invention mean the same as the layer formation step and the crosslinking step in the above-mentioned process for producing a relief printing starting plate for laser engraving, and preferred ranges are also the same.

### <Engraving Step>

The process for producing a relief printing plate of the present invention preferably comprises an engraving step of laser-engraving the relief printing starting plate having a crosslinked relief-forming layer.

The engraving step is a step of laser-engraving a crosslinked relief-forming layer that has been crosslinked in the crosslinking step to thus form a relief layer. Specifically, it is preferable to engrave a crosslinked relief-forming layer that has been crosslinked by irradiation with laser light according to a desired image, thus forming a relief layer. Furthermore, a step in which a crosslinked relief-forming layer is subjected to scanning irradiation by controlling a laser head using a computer in accordance with digital data of a desired image can preferably be cited.

This engraving step preferably employs an infrared laser. When irradiated with an infrared laser, molecules in the crosslinked relief-forming layer undergo molecular vibration, thus generating heat. When a high power laser such as a carbon dioxide laser or a YAG laser is used as the infrared laser, a large quantity of heat is generated in the laser-irradiated area, and molecules in the crosslinked relief-forming layer undergo molecular scission or ionization, thus being selectively removed, that is, engraved. The advantage of laser engraving is that, since the depth of engraving can be set freely, it is possible to control the structure three-dimensionally. For example, for an area where fine halftone dots are printed, carrying out engraving shallowly or with a shoulder prevents the relief from collapsing due to printing pressure, and for a groove area where a fine outline character is printed, carrying out engraving deeply makes it difficult for ink the groove to be blocked with ink, thus enabling breakup of an outline character to be suppressed.

In particular, when engraving is carried out using an infrared laser that corresponds to the absorption wavelength of the photothermal conversion agent, it becomes possible to selectively remove the crosslinked relief-forming layer at higher sensitivity, thus giving a relief layer having a sharp image.

As the infrared laser used in the engraving step, from the viewpoint of productivity, cost, etc., a carbon dioxide laser or a semiconductor laser is preferable. In particular, a fiber-coupled semiconductor infrared laser is preferably used. In general, compared with a CO₂ laser, a semiconductor laser has higher efficiency laser oscillation, is less expensive, and can be made smaller. Furthermore, it is easy to form an array due to the small size. Moreover, the shape of the beam can be controlled by treatment of the fiber.

With regard to the semiconductor laser, one having a wavelength of 700 to 1,300 nm may be used, but one having a wavelength of 800 to 1,200 nm is preferable, one having a wavelength of 860 to 1,200 nm is more preferable, and one having a wavelength of 900 to 1,100 nm is particularly preferable.

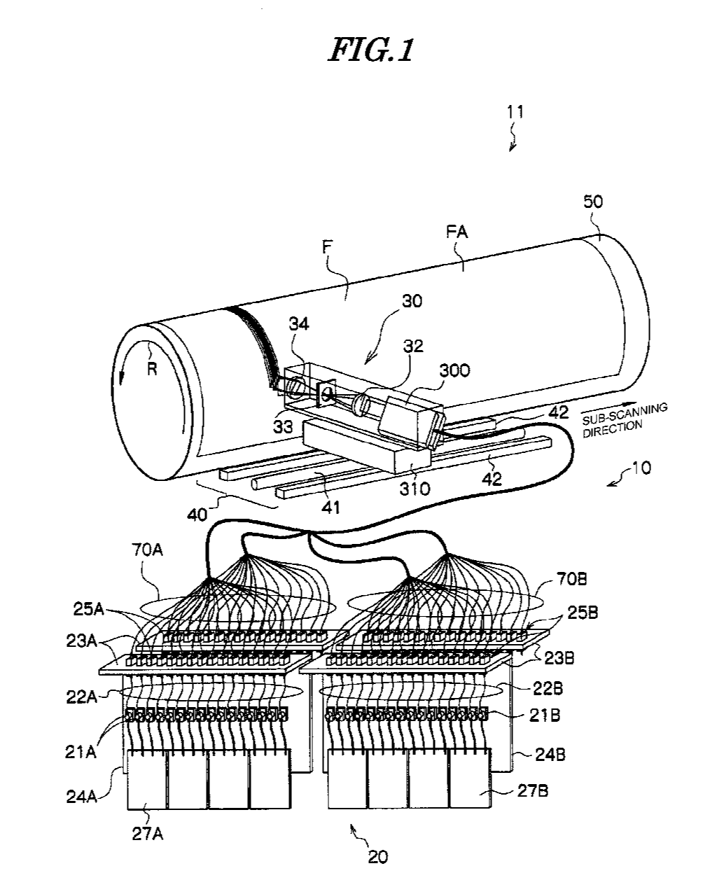

One embodiment of plate making equipment 11 comprising fiber-coupled semiconductor laser recording equipment 10 that can be used for making a relief printing plate using the relief printing starting plate of the present invention is explained below in terms of constitution by reference to FIG. 1.

The plate making equipment 11 comprising the fiber-coupled semiconductor laser recording equipment 10 that can be used in the present invention engraves (records) a two-dimensional image on a relief printing starting plate F of the present invention (recording medium) at high speed by rotating in a main scanning direction a drum 50 having on its outer peripheral face the relief printing starting plate F, irradiating the relief printing starting plate F with a plurality of laser beams at the same time according to image data of an image that is to be engraved (recorded), and scanning an exposure head 30 at a predetermined pitch in a sub-scanning direction, which is perpendicular to the main scanning direction. Furthermore, when a narrow region is engraved (precision engraving such as fine lines or halftone dots), the relief printing starting plate F is shallowly engraved, and when a wide region is engraved, the relief printing starting plate F is deeply engraved.

As shown in FIG. 1, the plate making equipment 11 is formed from the drum 50 equipped with the relief printing starting plate F, which is engraved by a laser beam to record an image, and rotated in the direction of arrow R in FIG. 1 so that the relief printing starting plate F moves in the main scanning direction, and the laser recording equipment 10. The laser recording equipment 10 comprises a light source unit 20 generating a plurality of laser beams, an exposure head 30 for exposing the relief printing starting plate F to the plurality of laser beams generated by the light source unit 20, and an exposure head moving part 40 that makes the exposure head 30 move along the sub-scanning direction of.

The light source unit 20 comprises semiconductor lasers 21A and 21B formed from broad area semiconductor lasers to which one end part of each of optical fibers 22A and 22B is individually coupled, light source boards 24A and 24B on the surface of which the semiconductor lasers 21A and 21B are disposed, adapter boards 23A and 23B mounted vertically on one end part of each of the light source boards 24A and 24B and provided with a plurality (the same as the number of semiconductor lasers 21A and 21B) of adapters of SC type light connectors 25A and 25B, and LD driver boards 27A and 27B mounted horizontally on the other end of each of the light source boards 24A and 24B and provided with an LD driver circuit (not illustrated) for driving the semiconductor lasers 21A and 21B in accordance with image data of an image that is to be engraved (recorded) on the relief printing starting plate F.

The exposure head 30 is provided with a fiber array part 300 that collects laser beams emitted by the plurality of semiconductor lasers 21A and 21B and emits them. Transmitted to this fiber array part 300 via a plurality of optical fibers 70A and 70B connected to the SC type light connectors 25A and 25B connected to the adapter boards 23A and 23B are laser beams emitted by the semiconductor lasers 21A and 21B.

As shown in FIG. 1, arranged in sequence on the exposure head 30 from the fiber array part 300 side are a collimator lens 32, an aperture member 33, and an imaging lens 34. The aperture member 33 is disposed so that the aperture is positioned in the far field when viewed from the fiber array part 300 side. This enables the same level of light intensity regulating effect to be given to all of the laser beams emitted from the optical fiber end parts (not illustrated) of the plurality of optical fibers 70A and 70B in the fiber array part 300.

A laser beam is focused in the vicinity of an exposure face (surface) FA of the relief printing starting plate F by imaging means formed from the collimator lens 32 and the imaging lens 34.

In order to make it possible to change the shape of the beam for the fiber-coupled semiconductor laser, from the viewpoint of efficient engraving and good fine line reproducibility it is preferable in the present invention to control the beam diameter on the exposure face (relief-forming layer surface) FA in the range of 10 μm to 80 μm by setting the imaging position in a region on the inner side (side in direction in which laser beam is advancing) from the exposure face FA.

The exposure head moving part 40 comprises a ball screw 41 and two rails 42 disposed with their longitudinal direction along the sub-scanning direction, and by driving a sub-scanning motor (not illustrated) for rotating the ball screw 41 it is possible to move a pedestal 310 having provided thereon the exposure head 30 in the sub-scanning direction while it is being guided by the rails 42. Furthermore, the drum 50 can be rotated in the direction of arrow R in FIG. 1 by driving a main scanning motor (not illustrated), thereby carrying out main scanning.

Moreover, when controlling the shape to be engraved, it is also possible to change the shape of an engraved region by changing the amount of energy supplied to the fiber-coupled semiconductor laser without changing the shape of the laser beam.

Specifically, there is a method in which control is carried out by changing the power of the semiconductor laser, and a method in which control is carried out by changing the laser illumination time.

The process for producing a relief printing plate of the present invention may as necessary further comprise, subsequent to the engraving step, a rinsing step, a drying step, and/or a post-crosslinking step, which are shown below.

Rinsing step: a step of rinsing the engraved surface by rinsing the engraved relief layer surface with water or a liquid containing water as a main component.

Drying step: a step of drying the engraved relief layer.

Post-crosslinking step: a step of further crosslinking the relief layer by applying energy to the engraved relief layer.

When engraving residue is attached to the engraved surface, a rinsing step of washing off engraving residue by rinsing the engraved surface with water or a liquid containing water as a main component may be added. Examples of rinsing means include a method in which washing is carried out with tap water, a method in which high pressure water is spray-jetted, and a method in which the engraved surface is brushed in the presence of mainly water using a batch or conveyor brush type washout machine known as a photosensitive resin letterpress plate processor, and when slime due to engraving residue cannot be eliminated, a rinsing liquid to which a surfactant is added may be used.

When the rinsing step of rinsing the engraved surface is carried out, it is preferable to add a drying step of drying an engraved relief-forming layer so as to evaporate rinsing liquid.

Furthermore, as necessary, a post-crosslinking step for further crosslinking the relief-forming layer may be added. By carrying out a post-crosslinking step, which is an additional crosslinking step, it is possible to further strengthen the relief formed by engraving.

As the rinsing liquid that can be used in the present invention, water or a liquid containing water as a main component is preferable.

The pH of the rinsing liquid is preferably at least 9, more preferably at least 10, and yet more preferably at least 11. The pH of the rinsing liquid is preferably no greater than 14, more preferably no greater than 13.5, yet more preferably no greater than 13.1, particularly preferably no greater than 13, and most preferably no greater than 12.5. When in the above-mentioned range, sufficient rinsing properties (washing properties) are obtained, and handling is easy.

In order to set the pH of the rinsing liquid in the above-mentioned range, the pH may be adjusted using an acid or a base as appropriate, and the acid or base used is not particularly limited. As a base for adjusting the pH, an inorganic base is preferable, and examples thereof include KOH and NaOH. When an acid is used for adjusting the pH, an inorganic acid is preferable, and examples thereof include HCl, H₂SO₄, phosphoric acid, and HNO₃.

The rinsing liquid that can be used in the present invention preferably comprises water as a main component.

The rinsing liquid may contain as a solvent other than water a water-miscible solvent such as an alcohol, acetone, or tetrahydrofuran.

The rinsing liquid for the relief printing plate making of the present invention preferably comprises a basic compound, and more preferably a water-soluble basic compound.

The basic compound is not particularly limited; a known basic compound may be used, an inorganic basic compound is preferable, an alkali metal salt compound and an alkaline earth metal salt compound are more preferable, and an alkali metal hydroxide is yet more preferable.

Examples of the basic compound include inorganic alkali salts such as sodium hydroxide, ammonium hydroxide, potassium hydroxide, lithium hydroxide, sodium silicate, potassium silicate, trisodium phosphate, tripotassium phosphate, triammonium phosphate, disodium phosphate, dipotassium phosphate, diammonium phosphate, sodium carbonate, potassium carbonate, ammonium carbonate, sodium bicarbonate, potassium bicarbonate, ammonium bicarbonate, sodium borate, potassium borate, and ammonium borate.

Furthermore, when an acid is used for adjusting the pH, an inorganic acid is preferable, and examples thereof include hydrochloric acid, sulfuric acid, phosphoric acid, and nitric acid.

The rinsing liquid preferably comprises a surfactant.

The surfactant is not particularly limited; a known surfactant may be used, and examples thereof include an anionic surfactant, a cationic surfactant, an amphoteric surfactant, and a nonionic surfactant.

Examples of the anionic surfactant include a fatty acid salt, an abietate, a hydroxyalkanesulfonate, an alkanesulfonate, an α-olefinsulfonate, a dialkylsulfosuccinate, an alkyl diphenyl ether disulfonate, a straight chain alkylbenzenesulfonate, a branched chain alkylbenzenesulfonate, an alkylnaphthalenesulfonate, an alkylphenoxypolyoxyethylenepropylsulfonate, a polyoxyethylene alkyl sulfophenyl ether, a sodium N-methyl-N-oleyltaurate, an N-alkylsulfosuccinic acid monoamide disodium salt, a petroleum sulfonate, sulfated castor oil, sulfated tallow oil, a fatty acid alkyl ester sulfate ester salt, an alkylsulfate ester salt, a polyoxyethylene alkyl ether sulfate ester salt, a fatty acid monoglyceride sulfate ester salt, a polyoxyethylene alkyl phenyl ether sulfate ester salt, a polyoxyethylene styryl phenyl ether sulfate ester salt, an alkylphosphate ester salt, a polyoxyethylene alkyl ether phosphate ester salt, a polyoxyethylene alkyl phenyl ether phosphate ester salt, a partially saponified styrene-maleic anhydride copolymer, a partially saponified olefin-maleic anhydride copolymer, and a naphthalenesulfonate formalin condensate.

Examples of the cationic surfactant include an alkylamine salt and a quaternary ammonium salt.

Examples of the amphoteric surfactant include an alkylcarboxybetaine, an alkylimidazoline, and an alkylaminocarboxylic acid.

Examples of the nonionic surfactant include a polyoxyethylene alkyl ether, a polyoxyethylene alkyl phenyl ether, polyoxyethylene polystyryl phenyl ether, polyoxyethylene polyoxypropylene alkyl ether, a glycerol fatty acid partial ester, a sorbitan fatty acid partial ester, a pentaerythritol fatty acid partial ester, propylene glycol monofatty acid ester, sucrose fatty acid partial ester, a polyoxyethylene sorbitan fatty acid partial ester, a polyoxyethylene sorbitol fatty acid partial ester, a polyethylene glycol fatty acid ester, a polyglycerol fatty acid partial ester, a fatty acid diethanolamide, an N,N-bis-2-hydroxyalkylamine, polyoxyethylene alkylamine, triethanolamine fatty acid ester, trialkylamine oxide, polypropylene glycol having a molecular weight of 200 to 5,000, trimethylolpropane, a glycerol or sorbitol polyoxyethylene or polyoxypropylene adduct, and an acetylene glycol system.

Furthermore, the surfactant that can be used in the present invention is preferably a carboxybetaine compound, a sulfobetaine compound, a phosphobetaine compound, an amine oxide compound, or a phosphine oxide compound.

Moreover, a fluorine-based or silicone-based nonionic surfactant may also be used in the same manner.

With regard to the surfactant, one type may be used on its own or two or more types may be used in combination.

It is not necessary to particularly limit the amount of surfactant used, but it is preferably 0.01 to 20 wt % relative to the total weight of the rinsing liquid, and more preferably 0.05 to 10 wt %.

The rinsing liquid preferably comprises an antifoaming agent.

As the antifoaming agent, a compound such as a usual silicone-based self-emulsifying type or emulsifying type, or a nonionic surfactant having an HLB (Hydrophile-Lipophile Balance) value of no greater than 5 may be used. A silicone antifoaming agent is preferable. Among them, any of an emulsion-dispersing type, a solubilization type, etc. may be used.

Specific examples of the antifoaming agent include TSA731 and TSA739 (both from Dow Corning Toray).

The content of the antifoaming agent is preferably 0.001 to 1.0 wt % of the rinsing liquid for relief printing plate making.

The relief printing plate of the present invention having a relief layer may be produced as described above.

From the viewpoint of satisfying suitability for various aspects of flexographic printing, such as abrasion resistance and ink transfer properties, the thickness of the relief layer of the relief printing plate is preferably at least 0.05 mm but no greater than 10 mm, more preferably at least 0.05 mm but no greater than 7 mm, and yet more preferably at least 0.05 mm but no greater than 0.3 mm.

Furthermore, the Shore A hardness of the relief layer of the relief printing plate is preferably at least 50° but no greater than 90°. When the Shore A hardness of the relief layer is at least 50°, even if fine halftone dots formed by engraving receive a strong printing pressure from a letterpress printer, they do not collapse and close up, and normal printing can be carried out. Furthermore, when the Shore A hardness of the relief layer is no greater than 90°, even for flexographic printing with kiss touch printing pressure it is possible to prevent patchy printing in a solid printed part.

The Shore A hardness in the present specification is a value measured by a durometer (a spring type rubber hardness meter) that presses an indenter (called a pressing needle or indenter) into the surface of a measurement target at 25° C. so as to deform it, measures the amount of deformation (indentation depth), and converts it into a numerical value.

A relief printing plate produced by the process for producing a relief printing plate of the present invention can be applied to printing by a letterpress printer using an oil-based ink or a UV ink as well as printing by a flexographic printer using a UV ink.

In accordance with the present invention, there can be provided a resin composition for laser engraving that can give a relief printing plate having excellent rinsing properties for engraving residue formed when carrying out laser engraving and having excellent aqueous ink resistance, printing durability, and ink transfer properties, a relief printing starting plate for laser engraving employing the resin composition for laser engraving and a process for producing same, and a relief printing plate and a process for making same.

### EXAMPLES

The present invention is explained in further detail below by reference to Examples, but the present invention should not be construed as being limited to the Examples.

The weight-average molecular weight (Mw) of polymers in the Examples means a value measured by a gel permeation chromatography (GPC) method unless otherwise specified.

### <Method for Measuring Glass Transition Temperature (Tg)>

A measurement pan of a differential scanning calorimeter (DSC) was charged with 20 mg of a binder polymer. This was heated under a flow of nitrogen gas from 30° C. to 250° C. at 10° C./min (1st run), and then cooled to 30° C. at −10° C./min.

Subsequently, it was again heated from 30° C. to 250° C. (2nd run).

The temperature at which the base line started to change from the low temperature side in the 2nd run was defined as the glass transition temperature (Tg).

### Synthesis Example 1

### Synthesis of A-1

A three-necked flask equipped with a stirrer and a condenser was charged with 28.4 parts by weight of methacryloyloxyethyl hydrogen phthalate (Wako Pure Chemical Industries, Ltd.) and, as a solvent, 48 parts by weight of methyl ethyl ketone (Wako Pure Chemical Industries, Ltd.). It was further charged with 20 parts by weight of (3-mercaptopropyl)trimethoxysilane (Tokyo Chemical Industry Co., Ltd.), subsequently with 0.1265 parts by weight of 2,2′-azobis(2,4-dimethylvaleronitrile) (product name: ‘V-65’, Wako Pure Chemical Industries, Ltd.), and heated at 70° C. for 3 hours while stirring. Following this, distillation under reduced pressure was carried out, thus giving 47 parts by weight of target crosslinking group-containing hydrophilic compound A-1.

Identification of A-1 was carried out by ¹H-NMR (deuterated chloroform solvent).

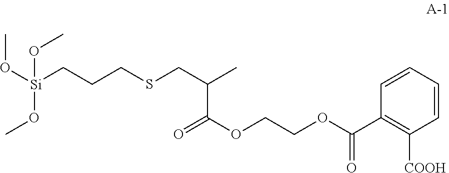

### Example 1

### <Preparation of Resin Composition 1 for Laser Engraving>

A three-necked flask equipped with a stirring blade and a condenser was charged with 50 parts by weight of polyvinyl butyral (#3000-2, Denki Kagaku Kogyo Kabushiki Kaisha) and, as a solvent, 47 parts by weight of propylene glycol monomethyl ether acetate, and heated at 70° C. for 120 minutes while stirring to thus dissolve the polyvinyl butyral. Subsequently, the solution was set at 40° C., 8 parts by weight of tributyl citrate (Wako Pure Chemical Industries, Ltd.) as a plasticizer and 1 part by weight of Ketjen Black EC600JD (carbon black, Lion Corporation) as a photothermal conversion agent were further added, and stirring was carried out for 30 minutes. Subsequently, 20 parts by weight of A-1 and, as a crosslinking agent, 15 parts by weight of KBE-846 (Shin-Etsu Chemical Co., Ltd.) were added, and stirring was carried out at 40° C. for 10 minutes. As a result of the above operations, flowable coating solution 1 for a crosslinkable relief-forming layer (resin composition 1 for laser engraving) was obtained.

### <Preparation of Relief Printing Starting Plate for Laser Engraving>

A spacer (frame) having a predetermined thickness was placed on a PET substrate, the coating solution 1 for a crosslinkable relief-forming layer obtained above was cast gently so that it did not overflow from the spacer (frame), and dried in an oven at 70° C. for 3 hours to provide a relief-forming layer having a thickness of about 1 mm, thus preparing relief printing starting plate 1 for laser engraving.

### <Preparation of Relief Printing Plate>

The relief-forming layer of the starting plate thus obtained was heated at 80° C. for 3 hours and further at 100° C. for 3 hours to thus thermally crosslink the relief-forming layer.

The crosslinked relief-forming layer after crosslinking was subjected to engraving by a carbon dioxide laser (CO₂ laser) or a fiber-coupled semiconductor laser, thus giving a relief printing plate.

As a carbon dioxide laser engraving machine, a CO₂ laser engraving machine (Adflex 250, Comtecs) was used. After a protection film was peeled off from the printing starting plate 1 for laser engraving, 1% to 10% halftone dots were formed using the carbon dioxide laser engraving machine under conditions of an output of 12 W, a head speed of 200 mm/sec, and a pitch setting of 2,400 DPI.

As a semiconductor laser engraving machine, laser recording equipment provided with a fiber-coupled semiconductor laser (FC-LD) SDL-6390 (JDSU, wavelength 915 nm) with a maximum power of 8.0 W was used. 1% to 10% halftone dots were formed using the semiconductor laser engraving machine under conditions of a laser output of 7.5 W, a head speed of 409 mm/sec, and a pitch setting of 2,400 DPI.

The thickness of the relief layer of the relief printing plate was about 1 mm.

Furthermore, when the Shore A hardness of the relief layer was measured by the above-mentioned measurement method, it was found to be 75°. Measurement of Shore hardness A was carried out in the same manner in each of the Examples and Comparative Examples described below.

### Example 2

### <Preparation of Resin Composition 2 for Laser Engraving>

A three-necked flask equipped with a stirring blade and a condenser was charged with 50 parts by weight of polyvinyl butyral (#3000-2, Denki Kagaku Kogyo Kabushiki Kaisha) and, as a solvent, 47 parts by weight of propylene glycol monomethyl ether acetate, and heated at 70° C. for 120 minutes while stirring to thus dissolve the polyvinyl butyral. Subsequently, the solution was set at 40° C., 15 parts by weight of diethylene glycol dimethacrylate (M-1, Tokyo Chemical Industry Co., Ltd.) as a polymerizable compound, 8 parts by weight of tributyl citrate (Wako Pure Chemical Industries, Ltd.) as a plasticizer, 1.6 parts by weight of Perbutyl Z (t-butyl peroxybenzoate, NOF Corporation) as a polymerization initiator, and 1 part by weight of Ketjen Black EC600JD (carbon black, Lion Corporation) as a photothermal conversion agent were further added, and stirring was carried out for 30 minutes. Subsequently, 20 parts by weight of A-1, 15 parts by weight of KBE-846 (Shin-Etsu Chemical Co., Ltd.) as a crosslinking agent, and 0.4 parts by weight of 1,8-diazabicyclo[5.4.0]undec-7-ene (DBU, Wako Pure Chemical Industries, Ltd.) were added, and stirring was carried out at 40° C. for 10 minutes. As a result of the above operations, flowable coating solution 2 for crosslinkable relief-forming layer (resin composition 2 for laser engraving) was obtained.

A relief printing starting plate for laser engraving and a relief printing plate were prepared in the same method as in Example 1 except that the resin composition 2 for laser engraving was used.

The thickness of the relief layer of the relief printing plate was about 1 mm.

### Example 3

A resin composition for laser engraving, a relief printing starting plate for laser engraving, and a relief printing plate were prepared by the same method as in Example 2 except that M-2 (glycerol 1,3-dimethacrylate (Tokyo Chemical Industry Co., Ltd.)) was used instead of diethylene glycol dimethacrylate.

The thickness of the relief layer of the relief printing plate was about 1 mm.

### Examples 4 to 27 and Comparative Examples 1 to 7

Resin compositions for laser engraving, relief printing starting plates for laser engraving, and relief printing plates were prepared by the same method as in Example 1 except that the components used for preparation of the crosslinkable resin composition for laser engraving were changed to those described in Table 2 and Table 3.

The thickness of the relief layers of these relief printing plates was about 1 mm.

TABLE 2

| | | | | Component (b) | | |
|---|---|---|---|---|---|---|
| | Component (a) | | | Specific | | |
| | Specific | | Glass transition | hydrophilic | | |
| | polymer | Reactive group | temp. | compound | Hydrophilic group | Bonding group |
| Example 1 | Polymer 1 | Hydroxy group | 20° C. or greater | A-1 | Carboxylic acid group | Trimethoxysilyl group |
| Example 2 | Polymer 1 | Hydroxy group | 20° C. or greater | A-1 | Carboxylic acid group | Trimethoxysilyl group |
| Example 3 | Polymer 1 | Hydroxy group | 20° C. or greater | A-1 | Carboxylic acid group | Trimethoxysilyl group |
| Example 4 | Polymer 1 | Hydroxy group | 20° C. or greater | A-1 | Carboxylic acid group | Trimethoxysilyl group |
| Example 5 | Polymer 1 | Hydroxy group | 20° C. or greater | A-1 | Carboxylic acid group | Trimethoxysilyl group |
| Example 6 | Polymer 1 | Hydroxy group | 20° C. or greater | A-1 | Carboxylic acid group | Trimethoxysilyl group |
| Example 7 | Polymer 1 | Hydroxy group | 20° C. or greater | A-1 | Carboxylic acid group | Trimethoxysilyl group |
| Example 8 | Polymer 1 | Hydroxy group | 20° C. or greater | A-1 | Carboxylic acid group | Trimethoxysilyl group |
| Example 9 | Polymer 1 | Hydroxy group | 20° C. or greater | A-1 | Carboxylic acid group | Trimethoxysilyl group |
| Example 10 | Polymer 2 | Hydroxy group | 20° C. or greater | A-1 | Carboxylic acid group | Trimethoxysilyl group |
| Example 11 | Polymer 3 | Hydroxy group | 20° C. or greater | A-1 | Carboxylic acid group | Trimethoxysilyl group |
| Example 12 | Polymer 4 | Hydroxy group | 20° C. or greater | A-1 | Carboxylic acid group | Trimethoxysilyl group |
| Example 13 | Polymer 5 | Hydroxy group | Less than 20° C. | A-1 | Carboxylic acid group | Trimethoxysilyl group |
| Example 14 | Polymer 6 | Carboxylic acid group | 20° C. or greater | A-1 | Carboxylic acid group | Trimethoxysilyl group |
| Example 15 | Polymer 7 | Carboxylic acid group | 20° C. or greater | A-1 | Carboxylic acid group | Trimethoxysilyl group |
| Example 16 | Polymer 1 | Hydroxy group | 20° C. or greater | A-11 | Carboxylic acid group | Isocyanate group |
| Example 17 | Polymer 2 | Hydroxy group | 20° C. or greater | A-11 | Carboxylic acid group | Isocyanate group |
| Example 18 | Polymer 3 | Hydroxy group | 20° C. or greater | A-11 | Carboxylic acid group | Isocyanate group |
| Example 19 | Polymer 4 | Hydroxy group | 20° C. or greater | A-11 | Carboxylic acid group | Isocyanate group |
| Example 20 | Polymer 1 | Hydroxy group | 20° C. or greater | A-12 | Carboxylic acid group | Epoxy group |

| | Component (c) | | | | |
|---|---|---|---|---|---|
| | Crosslinking agent | | | | Photothermal |
| | other than polymer- | Polymerizable | Polymerization | | conversion |
| | izable compound | compound | initiator | Catalyst | agent |
| Example 1 | KBE-846 | None | None | None | Carbon black |
| Example 2 | KBE-846 | M-1 | Perbutyl Z | DBU | Carbon black |
| Example 3 | KBE-846 | M-2 | Perbutyl Z | DBU | Carbon black |
| Example 4 | KBE-846 | None | None | None | ADS-820HO |
| Example 5 | KBE-846 | None | None | None | Carbon black |
| Example 6 | KBE-846 | None | None | None | Carbon black |
| Example 7 | KBE-3026 | None | None | None | Carbon black |
| Example 8 | X-12-965 | None | None | None | Carbon black |
| Example 9 | HMDI | None | None | None | Carbon black |
| Example 10 | KBE-846 | None | None | None | Carbon black |
| Example 11 | KBE-846 | None | None | None | Carbon black |
| Example 12 | KBE-846 | None | None | None | Carbon black |
| Example 13 | KBE-846 | None | None | None | Carbon black |
| Example 14 | KBE-846 | None | None | None | Carbon black |
| Example 15 | KBE-846 | None | None | None | Carbon black |
| Example 16 | KBE-846 | None | None | None | Carbon black |
| Example 17 | KBE-846 | None | None | None | Carbon black |
| Example 18 | KBE-846 | None | None | None | Carbon black |
| Example 19 | KBE-846 | None | None | None | Carbon black |
| Example 20 | KBE-846 | None | None | None | Carbon black |

TABLE 3

| | | | | Component (b) | | |
|---|---|---|---|---|---|---|
| | Component (a) | | | Specific | | |
| | Specific | | Glass transition | hydrophilic | | |
| | polymer | Reactive group | temp. | compound | Hydrophilic group | Bonding group |
| Example 21 | Polymer 2 | Hydroxy group | 20° C. or greater | A-12 | Carboxylic acid group | Epoxy group |
| Example 22 | Polymer 3 | Hydroxy group | 20° C. or greater | A-12 | Carboxylic acid group | Epoxy group |
| Example 23 | Polymer 4 | Hydroxy group | 20° C. or greater | A-12 | Carboxylic acid group | Epoxy group |
| Example 24 | Polymer 1 | Hydroxy group | 20° C. or greater | A-3 | Phosphoric acid group | Trimethoxysilyl group |
| Example 25 | Polymer 1 | Hydroxy group | 20° C. or greater | A-15 | Phosphoric acid group | Epoxy group |
| Example 26 | Polymer 1 | Hydroxy group | 20° C. or greater | A-16 | Sulfonic acid group | Epoxy group |
| Example 27 | Polymer 8 | Amino group | 20° C. or greater | A-9 | Sulfonic acid group | Acrylic group |
| Comp. Ex. 1 | Polymer 1 | Hydroxy group | 20° C. or greater | — | None | None |
| Comp. Ex. 2 | Polymer 1 | Hydroxy group | 20° C. or greater | A-1 | Carboxylic acid group | Trimethoxysilyl group |
| Comp. Ex. 3 | Polymer 9 | None | Less than 20° C. | — | None | None |
| Comp. Ex. 4 | Polymer 9 | None | Less than 20° C. | A-1 | Carboxylic acid group | Trimethoxysilyl group |
| Comp. Ex. 5 | Polymer 10 | None | Less than 20° C. | A-1 | Carboxylic acid group | Trimethoxysilyl group |
| Comp. Ex. 6 | Polymer 11 | None | Less than 20° C. | A-1 | Carboxylic acid group | Trimethoxysilyl group |
| Comp. Ex. 7 | Polymer 12 | Methacrylic group | Less than 20° C. | A-1 | Carboxylic acid group | Trimethoxysilyl group |

| | Component (c) | | | | |
|---|---|---|---|---|---|
| | Crosslinking agent | | | | Photothermal |
| | other than polymer- | Polymerizable | Polymerization | | conversion |
| | izable compound | compound | initiator | Catalyst | agent |
| Example 21 | KBE-846 | None | None | None | Carbon black |
| Example 22 | KBE-846 | None | None | None | Carbon black |
| Example 23 | KBE-846 | None | None | None | Carbon black |
| Example 24 | KBE-846 | None | None | None | Carbon black |
| Example 25 | KBE-846 | None | None | None | Carbon black |
| Example 26 | KBE-846 | None | None | None | Carbon black |
| Example 27 | HMDI | None | None | None | Carbon black |
| Comp. Ex. 1 | None | None | None | None | Carbon black |
| Comp. Ex. 2 | KBE-646 | None | None | None | Carbon black |
| Comp. Ex. 3 | KBE-646 | None | None | None | Carbon black |
| Comp. Ex. 4 | KBE-846 | None | None | None | Carbon black |
| Comp. Ex. 5 | KBE-846 | None | None | None | Carbon black |
| Comp. Ex. 6 | KBE-846 | None | None | None | Carbon black |
| Comp. Ex. 7 | KBE-846 | None | None | None | Carbon black |

Details of the abbreviations in Table 2 and Table 3 are as follows.
Polymer 1: Polyvinyl butyral (#3000-2 (product name; Denki Kagaku Kogyo Kabushiki Kaisha, Mw=90,000)
Polymer 2: Cellulose derivative (Ethylcellulose 45 (Wako Pure Chemical Industries, Ltd.))
Polymer 3: Modified epoxy resin (Arakyd 9201N, Arakawa Chemical Industries, Ltd., resin having hydroxy group)
Polymer 4: Acrylic resin (polyethylene glycol monomethacrylate (Blemmer PE200 (NOF Corporation))/methyl methacrylate=20/80 (molar ratio) copolymer (Mw=32,000))
Polymer 5: Acrylic resin (styrene/2-hydroxyethyl methacrylate/n-butyl methacrylate=20/50/30 (molar ratio) copolymer (Mw=56,000))
Polymer 6: Polyacrylic acid (P1600-AA, Sowa Kagaku, Mw=14,000)
Polymer 7: Resin having carboxy group (carboxylic acid group) (methacrylic acid/methyl methacrylate=70/30 (molar ratio) copolymer (Mw=50,000))
Polymer 8: Amino group-containing polymer (NK-350, Nippon Shokubai Co., Ltd., Mw=100,000)
Polymer 9: Styrene-isobutylene block copolymer (KRATON 107, Shell Chemical)
Polymer 10: Polyurethane elastomer (N2304, Nippon Polyurethane Industry Co., Ltd.)
Polymer 11: Ethylene-propylene-nonconjugated diene rubber (JSR EP21, JSR, ethylene units=61 wt %)
Polymer 12: Polymer in which terminal of addition polymer of polycarbonate diol (PCDL L4672, Asahi Kasei Chemicals Corporation, Mn=1,990)/tolylene diisocyanate 1/1 (molar ratio) is blocked by 1-methacryloyloxyethyl isocyanate
KBE-846 (Bis(triethoxysilylpropyl)tetrasulfide, Shin-Etsu Chemical Co., Ltd., difunctional silane coupling agent)
KBE-3026 (1,2-Bis(triethoxysilyl)ethane, Shin-Etsu Chemical Co., Ltd., difunctional silane coupling agent)
X-12-965 (Tris(3-trimethoxysilylpropyl)isocyanurate, Shin-Etsu Chemical Co., Ltd., trifunctional silane coupling agent)
HMDI (Tokyo Chemical Industry Co., Ltd., hexamethylene diisocyanate)
M-1: Diethylene glycol dimethacrylate
M-2: Glycerol 1,3-dimethacrylate (Tokyo Chemical Industry Co., Ltd.)
Perbutyl Z: t-Butyl peroxybenzoate (NOF Corporation)
DBU: 1,8-Diazabicyclo[5.4.0]undec-7-ene (Wako Pure Chemical Industries, Ltd.)
Carbon black: Ketjen Black EC600JD (Lion Corporation)
ADS-820HO: Cyanine dye (product name; American Dye Source, Inc.)

The evaluations below were carried out using the relief printing starting plates and the relief printing plates obtained in Examples 1 to 27 and Comparative Examples 1 to 7. The evaluation results are summarized in Table 4.

### <Aqueous Ink Resistance>

An immersion test was carried out using the aqueous ink SAC KI-74-19 black (product name; manufactured by Inctec) without dilution. After the PET support was peeled off from the relief printing starting plate having a crosslinked relief-forming layer, 5 g of the crosslinked relief-forming layer having a thickness of 1 mm was sampled, immersed in the aqueous ink under an atmosphere of 25° C. for 24 hours, then taken out, and dried at 100° C. for 5 hours, and the weight after drying was measured.

One with an amount remaining of at least 75% was evaluated as Excellent, one with at least 60% but less than 75% was evaluated as Good, one with at least 50% but less than 60% was evaluated as Fair, and one with less than 50% was evaluated as Poor.

### <Rinsing Properties>

A laser engraved relief printing plate was immersed in water and an engraved part was rubbed with a toothbrush (Clinics Toothbrush Flat, Lion Corporation) 10 times. Subsequently, the presence/absence of residue was checked by an optical microscope. When there was no residue, the evaluation was Excellent, when there was hardly any residue the evaluation was Good, when there was some residue remaining the evaluation was Fair, and when the residue could not be removed the evaluation was Poor.

### <Printing Durability>

A relief printing plate that had been obtained was set in a printer (ITM-4 type, Iyo Kikai Seisakujo Co., Ltd.), printing was continued using the aqueous ink Aqua SPZ16 rouge (Toyo Ink Mfg. Co., Ltd.) as an ink without dilution and Full Color Form M 70 (Nippon Paper industries Co., Ltd., thickness 100 μm) as printing paper, and 1% to 10% highlights were checked for the printed material. Completion of printing was defined as being when a halftone dot was not printed, and the length (meters) of paper printed up to the completion of printing was used as an index. The larger the value for the length of paper, the better the evaluation of printing durability.

### <Ink Transfer Properties>

In the above-mentioned evaluation of printing durability, the degree of ink adhering in a solid printed part on the printed material from starting printing up to 500 m and 1,000 m was visually compared. One that was uniform without unevenness in density was evaluated as Excellent, one that was uniform with hardly any unevenness in density was evaluated as Good, one with unevenness in density was evaluated as Poor, and a degree midway between Good and Poor was evaluated as Fair.

TABLE 4

| | Aqueous ink | Rinsing | Printing | Ink transfer |
|---|---|---|---|---|
| | resistance | properties | durability | properties |
| Example 1 | Excellent | Excellent | 3,200 m | Excellent |
| Example 2 | Excellent | Good | 3,200 m | Excellent |
| Example 3 | Excellent | Good | 3,200 m | Excellent |
| Example 4 | Excellent | Excellent | 2,800 m | Excellent |
| Example 5 | Excellent | Excellent | 2,800 m | Excellent |
| Example 6 | Excellent | Excellent | 2,000 m | Excellent |
| Example 7 | Excellent | Excellent | 2,000 m | Good |
| Example 8 | Good | Excellent | 3,000 m | Excellent |
| Example 9 | Excellent | Excellent | 2,000 m | Excellent |
| Example 10 | Excellent | Excellent | 3,000 m | Excellent |
| Example 11 | Excellent | Excellent | 3,000 m | Excellent |
| Example 12 | Excellent | Excellent | 3,000 m | Excellent |
| Example 13 | Good | Excellent | 2,000 m | Good |
| Example 14 | Good | Excellent | 2,000 m | Good |
| Example 15 | Good | Excellent | 2,000 m | Good |
| Example 16 | Excellent | Excellent | 2,500 m | Excellent |
| Example 17 | Excellent | Excellent | 2,500 m | Excellent |
| Example 18 | Excellent | Excellent | 2,500 m | Excellent |
| Example 19 | Excellent | Excellent | 2,500 m | Excellent |
| Example 20 | Excellent | Excellent | 2,000 m | Excellent |
| Example 21 | Excellent | Good | 2,000 m | Excellent |
| Example 22 | Excellent | Good | 2,000 m | Excellent |
| Example 23 | Excellent | Good | 2,000 m | Excellent |
| Example 24 | Excellent | Good | 2,000 m | Good |
| Example 25 | Good | Good | 2,000 m | Good |
| Example 26 | Good | Good | 2,000 m | Good |
| Example 27 | Good | Good | 2,000 m | Good |
| Comp. Ex. 1 | Poor | Poor | 800 m | Poor |
| Comp. Ex. 2 | Fair | Poor | 600 m | Fair |
| Comp. Ex. 3 | Poor | Poor | 600 m | Fair |
| Comp. Ex. 4 | Fair | Fair | 1,000 m | Fair |
| Comp. Ex. 5 | Fair | Fair | 1,000 m | Fair |
| Comp. Ex. 6 | Fair | Fair | 1,000 m | Fair |
| Comp. Ex. 7 | Fair | Fair | 1,000 m | Fair |

### EXPLANATION OF REFERENCE NUMERALS AND SYMBOLS

10: Laser recording equipment (exposure equipment)
11: Plate making equipment
20: Light source unit
21A, 21B: Semiconductor laser
22A, 22B: Optical fiber
23A, 23B: Adapter board
24A, 24B: Light source board
25A, 25B: SC type light connector
27A, 27B: LD driver board
30: Exposure head
32: Collimator lens (imaging means)
33: Aperture member
34: Imaging lens (imaging means)
40: Exposure head moving part
41: Ball screw
42: Rail
50: Drum
70A, 70B: Optical fiber
300: Fiber array part
310: Pedestal
F: Relief printing starting plate
FA: Exposure face (surface of relief printing starting plate)
R: Direction of rotation

What is claimed is:

1. A resin composition for laser engraving comprising;
(a) a binder polymer having a reactive group;
(b) a compound having a hydrophilic group and a bonding group that can react with the reactive group; and
(c) a crosslinking agent.

2. The resin composition for laser engraving according to claim 1, wherein the crosslinking agent (c) comprises the same functional group as the bonding group.

3. The resin composition for laser engraving according to claim 1, wherein the bonding group is at least one type of group selected from the group consisting of —SiR¹R²R³, an acid anhydride residue, a methacryloyl group, an acryloyl group, a styryl group, a vinyloxy group, an isocyanate group, a blocked isocyanate group, an amino group, a hydroxy group, —C(═O)—R⁴, an epoxy group, and a mercapto group,
wherein R¹ to R³ in —SiR¹R²R³ above independently denote a hydrogen atom, a halogen atom, or a monovalent organic group, at least one of R¹ to R³ is an alkyl group, an alkoxy group, or a halogen atom, and R⁴ in —C(═O)—R⁴ above denotes a hydrogen atom or an alkyl group.

4. The resin composition for laser engraving according to claim 1, wherein the number of bonding groups in the compound (b) having a hydrophilic group and a bonding group that can react with the reactive group is one.

5. The resin composition for laser engraving according to claim 1, wherein the hydrophilic group is at least one type of group selected from the group consisting of a sulfonic acid group, a phosphoric acid group, a phosphonic acid group, a carboxylic acid group, a hydroxy group, an amide group, and an amino group.

6. The resin composition for laser engraving according to claim 1, wherein the compound (b) having a hydrophilic group and a bonding group that can react with the reactive group is a compound represented by Formula (1) below
R^{a}-L-(-R^{b})ₘ (1)
wherein R^{a} denotes a bonding group that can react with the reactive group, R^{b} denotes a hydrophilic group, m denotes an integer of 1 to 3, and L denotes a single bond or an (m+1)-valent organic linking group.

7. The resin composition for laser engraving according to claim 1, wherein it further comprises (d) a crosslinking promoter.

8. The resin composition for laser engraving according to claim 1, wherein it further comprises (e) a photothermal conversion agent.

9. The resin composition for laser engraving according to claim 1, wherein it comprises a polymerization initiator and a polymerizable compound.

10. A relief printing starting plate for laser engraving, comprising a relief-forming layer comprising the resin composition for laser engraving according to claim 1.

11. A relief printing starting plate for laser engraving having a crosslinked relief-forming layer formed by crosslinking a relief-forming layer comprising the resin composition for laser engraving according to claim 1.

12. The relief printing starting plate for laser engraving according to claim 11, wherein the crosslinked relief-forming layer has a Shore A hardness of at least 50° but no greater than 90°.

13. A process for producing a relief printing starting plate for laser engraving, comprising:
a layer formation step of forming a relief-forming layer from the resin composition for laser engraving according to claim 1; and
a crosslinking step of crosslinking the relief-forming layer by heat and/or light to thus obtain a relief printing starting plate having a crosslinked relief-forming layer.

14. The process for producing a relief printing starting plate for laser engraving according to claim 13, wherein the crosslinking step is a step of crosslinking the relief-forming layer by heat.

15. A process for making a relief printing plate, comprising:
a layer formation step of forming a relief-forming layer from the resin composition for laser engraving according to claim 1;
a crosslinking step of crosslinking the relief-forming layer by heat and/or light to thus obtain a relief printing starting plate having a crosslinked relief-forming layer; and
an engraving step of laser-engraving the relief printing starting plate having a crosslinked relief-forming layer to thus form a relief layer.

16. The process for making a relief printing plate according to claim 15, wherein the relief layer has a thickness of at least 0.05 mm but no greater than 10 mm.

17. A relief printing plate made by the process for making a relief printing plate according to claim 15.
